(19) United States
(12) Patent Application Publication
(10) Pub. No.: US 2026/0150392 A1
(43) Pub. Date: May 28, 2026

(54) SEMICONDUCTOR STRUCTURE AND METHOD FOR MANUFACTURING THE SAME

(71) Applicant: Taiwan Semiconductor Manufacturing Company, Ltd., Hsinchu (TW)

(72) Inventors: Chun-Yen LIN, Hsinchu City (TW); Ting-Yun WU, Taipei City (TW); Wei-Cheng LIN, Taichung City (TW); Jiann-Tyng TZENG, Hsinchu (TW)

(21) Appl. No.: 18/956,564

(22) Filed: Nov. 22, 2024

(51) Int. Cl. H01L 27/092; H01L 21/8238; H01L 29/06; H01L 29/08; H01L 29/423; H01L 29/66; H01L 29/775; H01L 29/786

(52) U.S. Cl. CPC H10D 84/85; H10D 30/014; H10D 30/43; H10D 30/6735; H10D 30/6757; H10D 62/121; H10D 62/151; H10D 64/017; H10D 84/017; H10D 84/0186; H10D 84/038

(57) ABSTRACT

A method for manufacturing a semiconductor structure providing a first circuit cell and a second circuit cell arranged in a first direction. Each of the first circuit cell and the second circuit cell includes complementary field-effect transistors (CFETs) arranged in a second direction perpendicular to the first direction. Each of the CFETs includes a first transistor and a second transistor. The method further includes forming a first conductive structure between the first circuit cell and the second circuit cell in the first direction, and removing a portion of the first conductive structure to divide the first conductive structure into a first conductive wall and a second conductive wall separated from each other in the first direction. The first conductive wall is used for a local connection of the first circuit cell and the second conductive wall is used for a local connection of the second circuit cell.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) devices have been incorporated into memory devices (including, for example, static random-access memory, or SRAM, cells) and core devices (including, for example, standard logic, or STD, cells) to reduce the chip footprint while maintaining reasonable processing margins.

As GAA devices continue to be developed, complementary metal-oxide-semiconductor field effect transistors (CMOSFET or CFET) has been provided due to their high noise immunity and low static power consumption. However, although existing technologies for fabricating CFETs have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are top views (or layouts) of a semiconductor structure, in accordance with some embodiments of the present disclosure, in which FIG. 1A illustrates the features in a device region and a front-side interconnection structure, and

FIG. 1B illustrates the features in the device region and a back-side interconnection structure.

FIG. 1C is an X-Z cross-sectional view of the semiconductor structure along a line C-C′ in FIGS. 1A and 1B, in accordance with some embodiments of the present disclosure.

FIG. 1D is a Y-Z cross-sectional view of the semiconductor structure along a line D-D′ in FIGS. 1A and 1B, in accordance with some embodiments of the present disclosure.

FIG. 1E is a Y-Z cross-sectional view of the semiconductor structure along a line E-E′ in FIGS. 1A and 1B, in accordance with some embodiments of the present disclosure.

FIG. 1F is a Y-Z cross-sectional view of the semiconductor structure along a line F-F′ in FIGS. 1A and 1B, in accordance with some embodiments of the present disclosure.

FIG. 1G is a Y-Z cross-sectional view of the semiconductor structure along a line G-G′ in FIGS. 1A and 1B, in accordance with some embodiments of the present disclosure.

FIGS. 2 and 3 are perspective views of a workpiece for the semiconductor structure at various fabrication stages, in accordance with some embodiments of the present disclosure.

FIG. 4 is a top view (or a layout) of the workpiece at various fabrication stages, in accordance with some embodiments of the present disclosure.

FIG. 5 is an X-Z cross-sectional view of the workpiece at various fabrication stages along a line C-C′ in FIG. 4, in accordance with some embodiments of the present disclosure.

FIG. 6 is an X-Z cross-sectional view of the workpiece at various fabrication stages along the line C-C′ in FIG. 4, in accordance with some embodiments of the present disclosure.

FIG. 7 is an X-Z cross-sectional view of the workpiece at various fabrication stages along the line C-C′ in FIG. 4, in accordance with some embodiments of the present disclosure.

FIG. 8 is an X-Z cross-sectional view of the workpiece at various fabrication stages along the line C-C′ in FIG. 4, in accordance with some embodiments of the present disclosure.

FIG. 9 is an X-Z cross-sectional view of the workpiece at various fabrication stages along the line C-C′ in FIG. 4, in accordance with some embodiments of the present disclosure.

FIG. 10 is an X-Z cross-sectional view of the workpiece at various fabrication stages along the line C-C′ in FIG. 4, in accordance with some embodiments of the present disclosure.

FIG. 11A is a top view (or a layout) of the workpiece at various fabrication stages, in accordance with some embodiments of the present disclosure.

FIG. 11B is an X-Z cross-sectional view of the workpiece at various fabrication stages along the line C-C′ in FIG. 11A, in accordance with some embodiments of the present disclosure.

FIG. 12A is a top view (or a layout) of the workpiece at various fabrication stages, in accordance with some embodiments of the present disclosure.

FIGS. 12B, 12C, 12D, and 12E are Y-Z cross-sectional views of the workpiece at various fabrication stages along a line D-D′, a line E-E′, a line F-F′, and a line G-G′ in FIG. 12A, respectively, in accordance with some embodiments of the present disclosure.

FIG. 13A is a top view (or a layout) of the workpiece at various fabrication stages, in accordance with some embodiments of the present disclosure.

FIGS. 13B, 13C, 13D, and 13E are Y-Z cross-sectional views of the workpiece at various fabrication stages along a line D-D′, a line E-E′, a line F-F′, and a line G-G′ in FIG. 13A, respectively, in accordance with some embodiments of the present disclosure.

FIG. 14A is a top view (or a layout) of the workpiece at various fabrication stages, in accordance with some embodiments of the present disclosure.

FIGS. 14B, 14C, 14D, and 14E are Y-Z cross-sectional views of the workpiece at various fabrication stages along a line D-D′, a line E-E′, a line F-F′, and a line G-G′ in FIG. 14A, respectively, in accordance with some embodiments of the present disclosure.

FIG. 15A is a top view (or a layout) of the workpiece at various fabrication stages, in accordance with some embodiments of the present disclosure.

FIG. 15B is an X-Z cross-sectional view of the workpiece at various fabrication stages along a line C-C′ in FIG. 15A, in accordance with some embodiments of the present disclosure.

FIGS. 15C, 15D, 15E, and 15F are Y-Z cross-sectional views of the workpiece at various fabrication stages along a line D-D′, a line E-E′, a line F-F′, and a line G-G′ in FIG. 15A, respectively, in accordance with some embodiments of the present disclosure.

FIG. 16A is a top view (or a layout) of the workpiece at various fabrication stages, in accordance with some embodiments of the present disclosure.

FIG. 16B is an X-Z cross-sectional view of the workpiece at various fabrication stages along a line C-C′ in FIG. 16A, in accordance with some embodiments of the present disclosure.

FIGS. 16C, 16D, 16E, and 16F are Y-Z cross-sectional views of the workpiece at various fabrication stages along a line D-D′, a line E-E′, a line F-F′, and a line G-G′ in FIG. 16A, respectively, in accordance with some embodiments of the present disclosure.

FIG. 17 is a Y-Z cross-sectional view of the semiconductor structure along a line F-F′ in FIGS. 1A and 1B, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to field-effect transistors (FETs), such as three-dimensional complementary field effect transistors (CFETs) with gate-all-around (GAA) structures, in memory (e.g., SRAM) and/or standard logic cells of an integrated circuit (IC) structure. Generally, a complementary field-effect transistor (CFET) may include an n-type FET (NFET) and a p-type FET (PFET) disposed vertically with a plurality of vertically stacked sheets (e.g., nanosheets), wires (e.g., nanowires), or rods (e.g., nanorods) in a channel region of the CFET, thereby allowing better gate control, lowered leakage current, and improved scaling capability for various IC applications. While existing technologies for fabricating CFETs have been generally adequate for their intended applications, they have not been entirely satisfactory in all aspects.

The gate-all-around (GAA) structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures including a CFET with an interconnection wall formed by cutting process to enhance process window and improve CFET design. The details of the structure and fabrication methods of the present disclosure are described below in conjunction with the accompanying drawings, which illustrate the processes and the structures for CFET, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated.

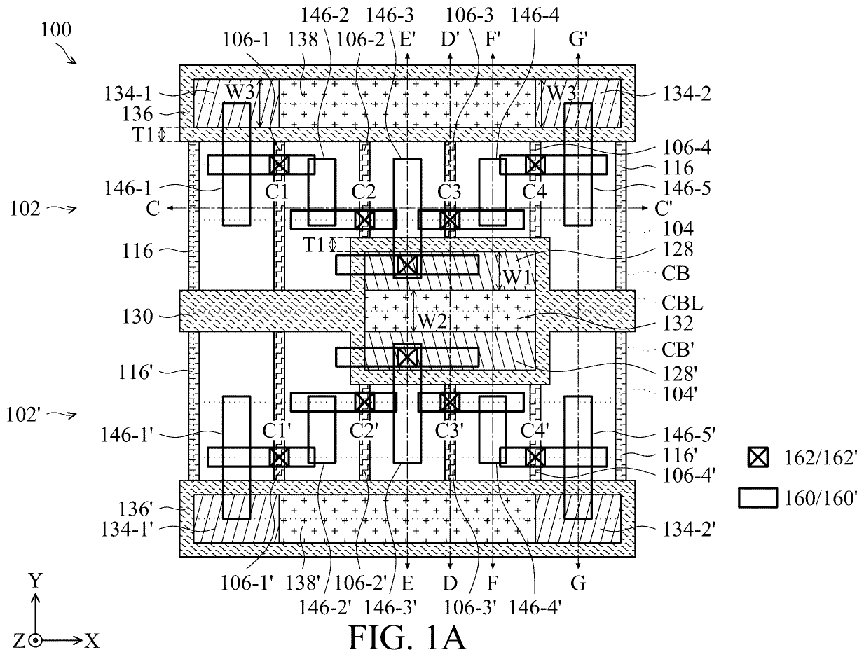

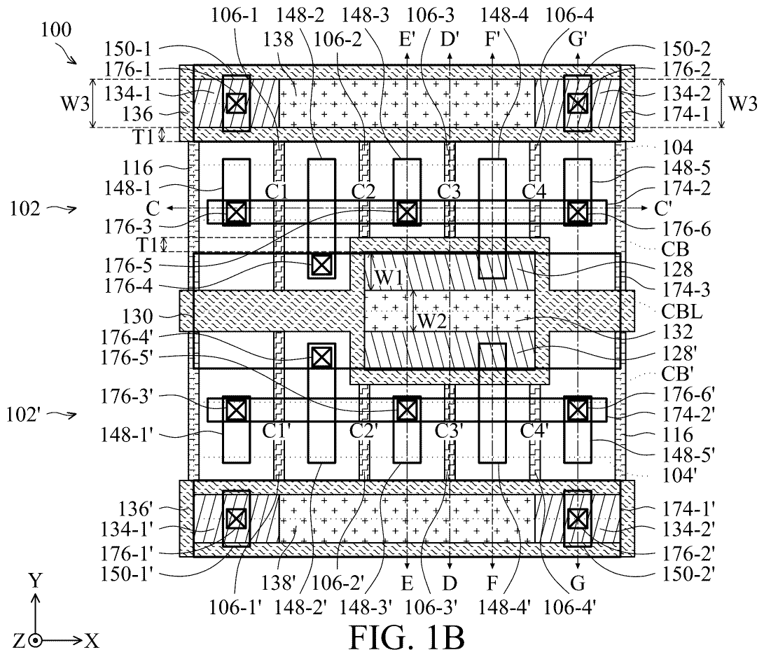

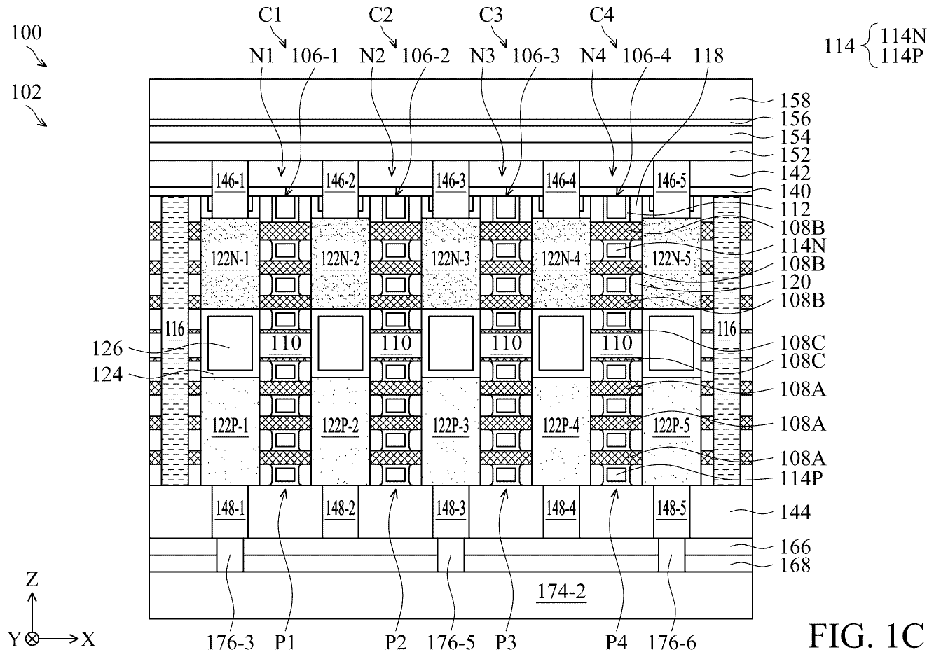

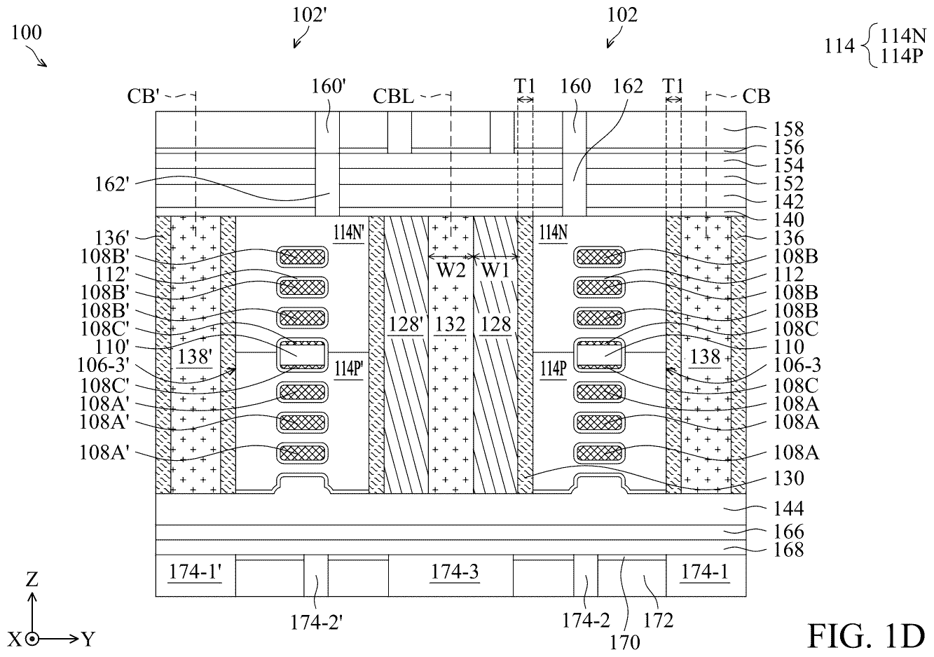

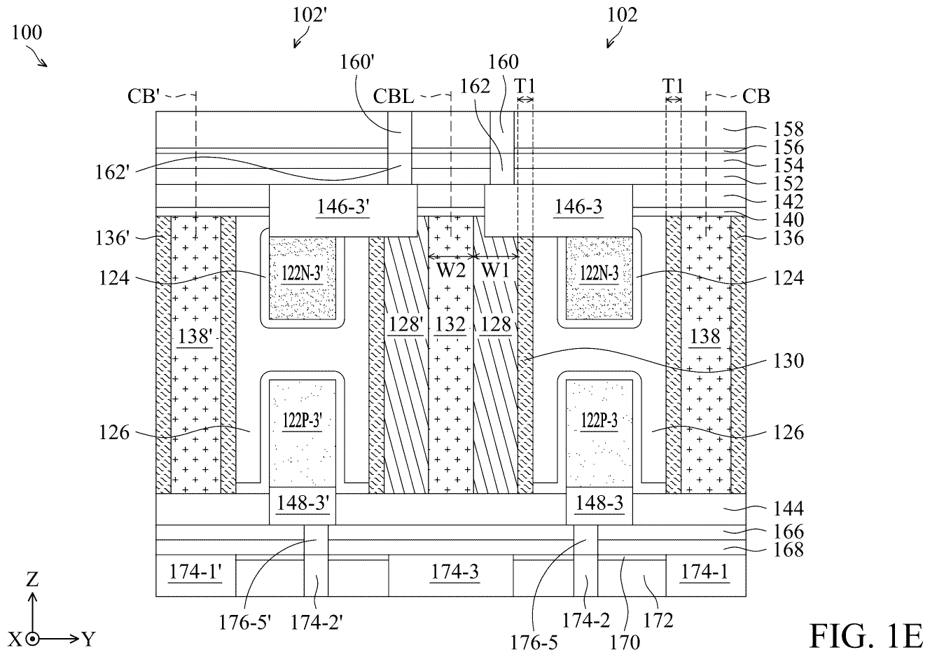

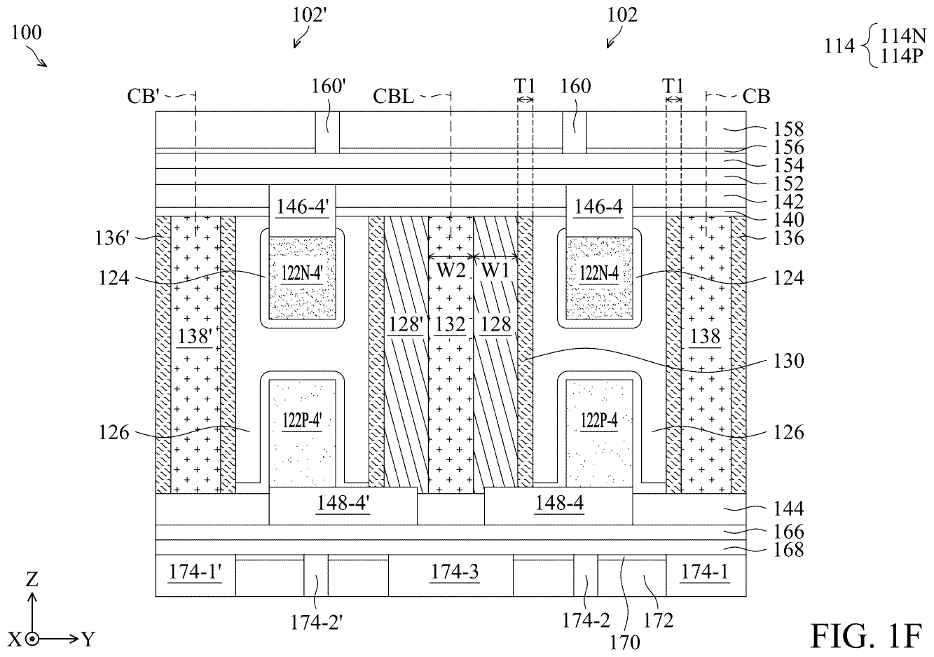

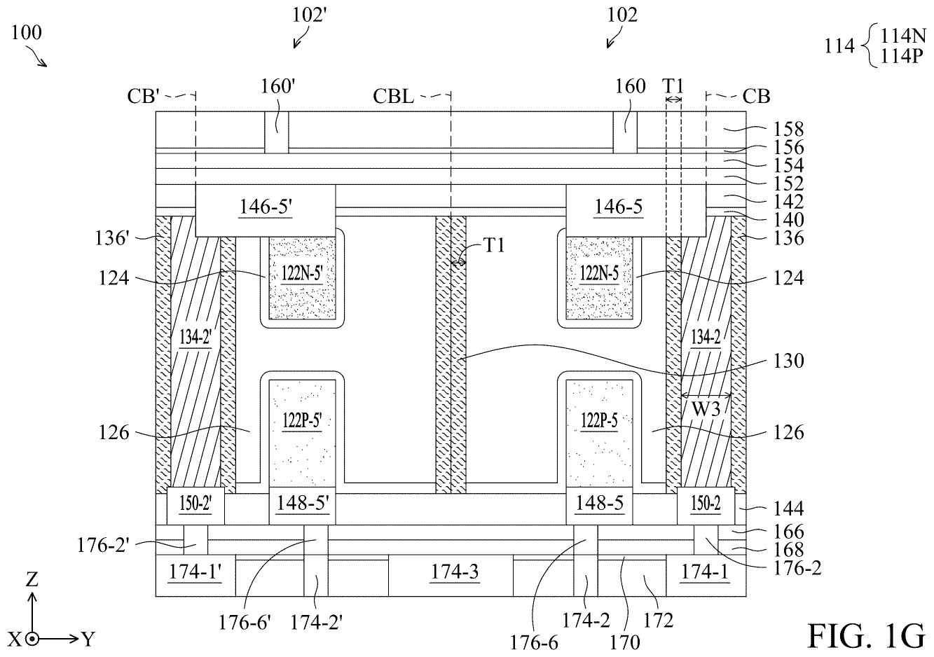

FIGS. 1A and 1B are top views (or layouts) of a semiconductor structure 100, in accordance with some embodiments of the present disclosure, in which FIG. A illustrates the features in a device region (including CFETs transistors and front-side source/drain contacts) and a front-side interconnection structure (including vias and metal conductors), and FIG. 1B illustrates the features in the device region (including the CFETs transistors and back-side source/drain contacts) and a back-side interconnection structure (including vias and metal conductors).

FIG. 1C is an X-Z cross-sectional view of the semiconductor structure 100 along a line C-C′ in FIGS. 1A and 1B, in accordance with some embodiments of the present disclosure. FIG. 1D is a Y-Z cross-sectional view of the semiconductor structure 100 along a line D-D′ in FIGS. 1A and 1B, in accordance with some embodiments of the present disclosure. FIG. 1E is a Y-Z cross-sectional view of the semiconductor structure 100 along a line E-E′ in FIGS. 1A and 1B, in accordance with some embodiments of the present disclosure. FIG. 1F is a Y-Z cross-sectional view of the semiconductor structure 100 along a line F-F′ in FIGS. 1A and 1B, in accordance with some embodiments of the present disclosure. FIG. 1G is a Y-Z cross-sectional view of the semiconductor structure 100 along a line G-G′ in FIGS. 1A and 1B, in accordance with some embodiments of the present disclosure.

Referring to FIGS. 1A and 1B, the semiconductor structure 100 includes circuit cells 102 and 102′. The circuit cells 102 and 102′ respectively has a cell boundary CB and a cell boundary CB′. As shown in FIGS. 1A and 1B, the circuit cells 102 and 102′ are arranged in the Y-direction. More specifically, the circuit cells 102 and 102′ are abutted together in the Y-direction, such that the cell boundary CB abuts the cell boundary CB′ in the Y-direction to share a cell boundary line CBL, as shown in FIGS. 1A and 1B.

It is noted that the circuit cells 102 and 102′ have the same function and operation. The circuit cells 102 and 102′ also have the same features, components, and structures. As shown in FIGS. 1A and 1B, the circuit cells 102 and 102′ have horizontal line symmetry along the X-direction. More specifically, the circuit cells 102 and 102′ are symmetrical along the cell boundary line CBL. For the sake of distinction and simplicity, the reference numbers of the features/components in the circuit cell 102′ similar or the same as that shown in the circuit cell 102 are additionally labeled with “′” and may not repeatedly described in detail. More specifically, if some features/components in the circuit cell 102 are described below, it should be understood that there are similar or the same features/components (having the reference numbers labeled with “′”) in the circuit cell 102, and the features/components in the circuit cell 102 and the features/components (having the reference numbers labeled with “′”) in the circuit cell 102′ are symmetrically configured.

Although the semiconductor structure 100 shown in FIGS. 1A and 1B includes two circuit cells 102 and 102′, it should be noted that the semiconductor structure 100 may include more circuit cells similar to the circuit cells 102 and 102′ arranged in rows and columns into an array, in accordance with some embodiments.

As shown in FIGS. 1A and 1B, the circuit cells 102 and 102′ respectively include active areas 104 and 104′. The active areas 104 and 104′ extend lengthwise in the X-direction and are arranged in the Y-direction. Each of active areas 104 and 104′ includes channel regions (including semiconductor layers 108A and 108B), source regions, and drain regions (where source regions and drain regions are collectively referred to as source/drain regions herein) of transistors.

The semiconductor structure 100 further includes gate structures, such as gate structures 106-1 to 106-4 for the circuit cell 102 and 106-1′ to 106-4′ for the circuit cell 102′ (may be collectively referred to as gate structures 106 for the circuit cell 102 and gate structures 106′ for the circuit cell 102′) that extend lengthwise in the Y-direction. The X-direction and the Y-direction are perpendicular. The gate structures 106 and 106′ are disposed over the channel regions of the respective active areas 104 and 104′ (i.e., (vertically stacked) semiconductor layers 108A and 108B in the channel regions of the active area 104 and (vertically stacked) semiconductor layers 108A′ and 108B′ in the channel regions of the active area 104′) and disposed between respective source/drain regions of the active areas 104 and 104′ (i.e., source/drain features). In some embodiments, the gate structures 106 and 106′ respectively wrap and/or surround suspended, vertically stacked semiconductor layers 108A and 108B in the channel regions of the active area 104 and suspended, vertically stacked semiconductor layers 108A′ and 108B′ in the channel regions of the active area 104′, respectively (as shown in FIGS. 1A and 1B).

The gate structures engage the active areas to form the CFETs. As shown in FIGS. 1A and 1B, in the circuit cell 102, the gate structure 106-1 to 106-4 extend across the active area 104 in the top view and engages the active area 104 to respectively form CFETs C1 to C4. Furthermore, in the circuit cell 102′, it should be understood that the gate structure 106-1′ to 106-4′ extend across the active area 104′ in the top view and engages the active area 104′ to respectively form CFETs C1′ to C4′.

As shown in FIGS. 1A and 1B, in the circuit cell 102, the CFETs C1 to C4 are arranged in the X-direction. Each of the of the CFETs C1 to C4 in the circuit cell 102 includes a p-type transistor (e.g., p-type transistor P1 to P4 for the CFETs C1 to C4) and an n-type transistor (e.g., n-type transistor N1 to N4 for the CFETs C1 to C4) over the p-type transistor. Therefore, the p-type transistor P1 to P4 and the n-type transistor N1 to N4 are also arranged in the X-direction. Furthermore, the p-type transistors P1 and the n-type transistors N1 share the gate structure 106-1; the p-type transistors P2 and the n-type transistors N2 share the gate structure 106-2; the p-type transistors P3 and the n-type transistors N3 share the gate structure 106-3; and the p-type transistors P4 and the n-type transistors N4 share the gate structure 106-4. It should be understood that the CFETs C1′ to C4′ in the circuit cell 102′ also includes p-type transistor P1′ to P4′ and n-type transistor N1′ to N4′ with similar configurations.

Each of the CFETs C1 to C4 includes two groups of semiconductor layers, such as semiconductor layers 108A and semiconductor layers 108B (may be collectively referred to as the semiconductor layers 108), as shown in FIGS. 1C to 1G. In some embodiments, the semiconductor layers 108 may also be referred to as channels, channel layers, nanostructures, nanosheets, or nanowires. The semiconductor layers 108A are used for the p-type transistors (e.g., the p-type transistors P1 to P4) and the semiconductor layers 108B are used for the n-type transistor (e.g., the n-type transistors N1 to N4) in the active area 104. As shown in FIGS. 1E to 1G, the semiconductor layers 108A and 108B are suspended. In some embodiments, the semiconductor layers 108 extend in the X-direction and vertically stacked (or arranged) in the Z-direction, as shown in FIG. 1C. Furthermore, in each of the CFETs C1 to C4, the semiconductor layers 108B are disposed over the semiconductor layers 108A, as shown in FIGS. 1C to 1G. More specifically, the semiconductor layers 108A are spaced apart from each other in the Z-direction, the semiconductor layers 108B are spaced apart from each other in the Z-direction, and the semiconductor layers 108B are over and spaced apart from the semiconductor layers 108A.

In some embodiments, three semiconductor layers 108 are vertically stacked (or vertically arranged) from each other in the Z-direction for one transistor (e.g., the p-type transistors P1 to P4 and the n-type transistors N1 to N4). For example, as shown in FIG. 1C, in one CFET C3, the n-type transistor N3 has three semiconductor layers 108B vertically stacked from each other in the Z-direction and the p-type transistor P3 has three nanostructures vertically stacked from each other in the Z-direction. However, there may be another appropriate number of nanostructures in one transistor. For example, there may be from 2 to semiconductor layers 108 in one transistor.

As shown in FIGS. 1C and 1D, each of the CFETs C1 to C4 further includes a dielectric layer 110 and two semiconductor layers 108C. In some embodiments, in each of the CFETs C1 to C4, the dielectric layer 110 and the semiconductor layers 108C are vertically between the semiconductor layers 108A and the semiconductor layers 108B. Furthermore, the dielectric layers 110 and the semiconductor layers 108C are vertically separated from the semiconductor layers 108A and the semiconductor layers 108B, as shown in FIGS. 1C and 1D. In some aspects, the dielectric layers 110 and the semiconductor layers 108C are over the semiconductor layers 108A and under the semiconductor layers 108B. As shown in FIGS. 1C and 1D, the semiconductor layers 108C are on and in contact with top surfaces and bottom surfaces of the dielectric layer 110. As shown in FIGS. 1C and 1D, in some aspects, the gate structures 106-1 to 106-4 also respectively wrap and/or surround the dielectric layers 110 and the semiconductor layers 108C.

In some embodiments, the dielectric material of dielectric layers 110 includes silicon, oxygen, carbon, nitrogen, other suitable material, or combinations thereof (for example, silicon oxide (SiO₂), silicon nitride (SiN), silicon oxynitride (SiON), silicon oxycarbide (SiOC), silicon carbon nitride (SiCN), silicon oxycarbon nitride (SiOCN)). The semiconductor layers 108A, 108B, and 108C may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the semiconductor layers 108A, 108B, and 108C include silicon for n-type transistors, such as the n-type transistors N1 to N4. In other embodiments, the semiconductor layers 108A, 108B, and 108C include silicon germanium for p-type transistors, such as the p-type transistors P1 to P4. In some embodiments, the semiconductor layers 108A, 108B, and 108C are all made of silicon, and the type of the transistors depends on the work function metal layer wrapping around the semiconductor layers 108A and 108B. In some embodiments, the semiconductor layers 108A, 108B, and 108C are epitaxially grown using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized. It should be understood that the CFETs C1′ to C4′ in the circuit cell 102′ may also include the semiconductor layers 108A′, 108B′, and 108C′ and the dielectric layers 110′ with similar configurations.

As shown in FIGS. 1A to 1D, each of the gate structures 106-1 to 106-4 has a gate dielectric layer 112 and a gate electrode layer 114 (including gate electrode layers 114P and 114N). The gate dielectric layers 112 wrap around each of the semiconductor layers 108A and 108B and the gate electrode layers 114 wrap around the gate dielectric layer 112 and the semiconductor layers 108A and 108B. In some embodiments, each of the gate structures 106-1 to 106-4 further includes an interfacial layer (such as silicon dioxide, silicon oxynitride, or other suitable materials) between the gate dielectric layers 112 and the semiconductor layers 108A and 108B. The gate dielectric layers 112 may include a dielectric material having a dielectric constant greater than a dielectric constant of SiO₂, which is approximately 3.9. The gate dielectric layers 112 may include oxide with nitrogen doped dielectric material (initial layer) combined with metal content high-K dielectric material (K value (dielectric constant) >13). For example, gate dielectric layers 112 may include hafnium oxide (HfO₂), which has a dielectric constant in a range from about 18 to about 40. Alternatively, the gate dielectric layers 112 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The gate dielectric layers 112 may be formed by chemical oxidation, thermal oxidation, ALD, CVD, and/or other suitable methods.

The gate electrode layers 114 are formed to wrap around the gate dielectric layer 112, the center portions of the semiconductor layers 108A and 108B, and the interfacial layers (if present), as shown in FIGS. 1C and 1D. Each of the gate electrode layers 114 has the gate electrode layer 114P for the p-type transistor (e.g. the p-type transistors P1 to P4) of the CFET and the gate electrode layer 114N for the n-type transistor (e.g. the n-type transistors N1 to N4) of the CFET. More specifically, the gate electrode layers 114P are used for the p-type transistors P1 to P4 of the CFETs C1 to C4 to wrap around the semiconductor layers 108A, the gate dielectric layer 112, and the interfacial layers (if present). The gate electrode layers 114N are used for the n-type transistors N1 to N4 of the CFETs C1 to C4 to wrap around the semiconductor layers 108B, the gate dielectric layer 112, and the interfacial layers (if present). In some embodiments, the gate electrode layers 114N are directly over and in contact with the gate electrode layers 114P, as shown in FIGS. 1C and 1D.

Each of the gate electrode layers 114N may include an n-type work function metal layer. In some embodiments, the n-type work function metal layer include a material such as Ti, Al, Ag, Mn, Zr, TiAl, TiAlC, TaC, TaCN, TaSiN, TaAl, TaAlC, TiAlN, other suitable n-type work function materials, or combinations thereof. For example, the n-type work function metal layer may be deposited utilizing ALD, CVD, or the like. However, any suitable materials and processes may be utilized to form the n-type work function metal layer.

Each of the gate electrode layers 114P may include a p-type work function metal layer. In some embodiments, the p-type work function metal layer include a material such as TiN, TaN, Ru, Mo, Al, WN, ZrSi₂, MoSi₂, TaSi₂, NiSi₂, other metal oxides, metal nitrides, metal silicates, transition metal-oxides, transition metal-nitrides, transition metal-silicates, oxynitrides of metals, metal aluminates, zirconium silicate, zirconium aluminate, other suitable p-type work function materials, combinations of these, or the like. Additionally, the p-type work function metal layer may be deposited using a deposition process such as ALD, CVD, or the like, although any suitable deposition process may be used.

In some embodiments, the gate electrode layers 114 may include a single layer or alternatively a multi-layer structure. In some embodiments, each of the gate electrode layers 114 may further include a capping layer, a barrier layer, and a fill material (not shown). The capping layer may be formed adjacent to the gate dielectric layers 112 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as ALD, CVD, or the like, although any suitable deposition process may be used. The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

It should be understood that each of the gate structures 106′ in the circuit cell 102′ also include a gate dielectric layer 112′ and a gate electrode layer 114′ (including a gate electrode layer 114N′ and a gate electrode layer 114P′) with similar configurations.

The circuit cell 102 further includes dielectric structures 116 for separating the circuit cell 102 from other circuit cells, transistors, or devices. The dielectric structures 116 extend lengthwise in the Y-direction. Furthermore, the dielectric structures 116 lengthwise overlap the cell boundary CB of the circuit cell 102, as shown in FIGS. 1A and 1B. The dielectric structures 116 and the CFETs C1 to C4 are arranged in the X-direction. More specifically, as shown in FIGS. 1A and 1B, two dielectric gate structures 116 and the CFETs C1 to C4 (or the gate structures 106-1 to 106-4) are arranged in the X-direction. In some embodiments, the CFETs C1 to C4 (or the gate structures 304-1 to 304-4) are between the two dielectric structures 116 in the X-direction, as shown in FIGS. 1A and 1B. In some aspects, the two dielectric gate structures 116 are disposed on opposite sides of the CFETs C1 to C4 (or the gate structures 106-1 to 106-4).

The dielectric structures 116 may be made of electrically insulating materials (e.g., dielectric materials) to provide electrical isolation between various circuit cells. In some embodiments, the dielectric structures 116 may be single dielectric layer or multiple layers and selected from a group consisting of SiO₂, SiOC, SiON, SiOCN, carbon content oxide, nitrogen content oxide, carbon and nitrogen content oxide, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), multiple metal content oxide, or combinations thereof. It should be understood that the circuit cell 102′ also includes dielectric structures 116′ with similar configurations.

The circuit cell 102 further include gate spacers 118 on opposite sides of the gate structure 106. More specifically, the gate spacers 118 are on sidewalls of the gate structures 106 and over the semiconductor layers 108, as shown in FIG. 1C. Furthermore, as shown in FIG. 1C, the gate spacers 118 are over and on (top surfaces of) the side portions of the (topmost) semiconductor layers 108 (specifically, the (topmost) semiconductor layers 108B), in accordance with some embodiments. The gate spacers 118 are over the semiconductor layers 108 and on top sidewalls of the gate structures 106, and thus are also referred to as gate top spacers or top spacers.

The gate spacers 118 may include multiple dielectric materials and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. In some embodiments, the gate spacers 118 may include a single layer or a multi-layer structure.

As shown in FIG. 1C, the circuit cell 102 further include inner spacers 120 on the sidewalls of the gate structures 106 and below the topmost semiconductor layers 108 (specifically, the (topmost) semiconductor layers 108B). More specifically, the inner spacers 120 are on the sidewalls of the gate structures 106, and below the gate spacers 118 and the topmost semiconductor layers 108. As shown in FIG. 1C, the inner spacers 120 are also vertically between (the side portions of) adjacent semiconductor layers 108B, vertically between (the side portions of) adjacent semiconductor layers 108B and 108A, vertically between (the side portions of) adjacent semiconductor layers 108 108A, and vertically between (bottommost) semiconductor layers 108A and a dielectric layer 144 (discussed below), in accordance with some embodiments. Furthermore, the inner spacers 120 are laterally between the source/drain features 122N/122P and the gate structures 106 in the X-direction, as shown in FIG. 1C.

The inner spacers 120 may include a dielectric material having higher K value (dielectric constant) than the gate spacers 118 and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof. In some embodiments, the thickness of the gate spacers 118 in the X-direction and the thickness of the inner spacers 120 in the X-direction are the same. It should be understood that the circuit cell 102′ also includes gate spacers 118′ and inner spacers 120′.

Referring to FIGS. 1C to 1G, the circuit cell 102 further include source/drain features 122N-1 to 122N-5 (may be collectively referred to as source/drain features 122N) and source/drain features 122P-1 to 122P-5 (may be collectively referred to as source/drain features 122P) in the source/drain regions of the active area 104. More specifically, the source/drain features 122P are disposed over the dielectric layer 144 and the source/drain features 122N are disposed over the source/drain features 122P. In some aspects, the source/drain features 122N are disposed higher than the source/drain features 122P. In some embodiments, the source/drain features 122N are vertically separated from the source/drain features 122P in the Z-direction, as shown in FIGS. 1C to 1G.

The source/drain features 122N are disposed on opposite sides of the respective gate structures 106 in the X-direction and connected by the semiconductor layers 108B to form the n-type transistors (e.g., the n-type transistors N1 to N₄ of the CFETs C1 to C4). Similarly, the source/drain features 122P are disposed on opposite sides of the respective gate structures 106 in the X-direction and connected by the semiconductor layers 108A to form the p-type transistors (e.g., the p-type transistors P1 to P4 of the CFETs C1 to C4).

The semiconductor layers 108A and 108B extend in the X-direction to connect one source/drain feature 122N/122P to the other source/drain feature 122N/122P. More specifically, the source/drain features 122P are disposed on opposite sides of the semiconductor layers 108A in the X-direction and the source/drain features 122N are disposed on opposite sides of the semiconductor layers 108B in the X-direction. Therefore, the source/drain features 122P are attached and electrically connected to the semiconductor layers 108A in the X-direction and the source/drain features 122N are attached and electrically connected to the semiconductor layers 108B in the X-direction, as shown in FIG. 1C. The source/drain features 122N/122P may also be referred to as source/drain, or source/drain regions. Furthermore, every two adjacent transistors in the X-direction share one source/drain feature 122N and one source/drain feature 122P, as shown in FIG. 1C. In some embodiments, source/drain feature(s) may refer to a source or a drain, individually or collectively dependent upon the context.

The source/drain features 122N and 122P may be formed by using an epitaxial growth process. In some embodiments, the source/drain features 122N may include epitaxially-grown material selected from a group consisting of SiP, SiC, SiPC, SiAs, Si, or a combination thereof. In some embodiments, the epitaxially-grown material of the source/drain features 122N may be doped with n-type dopants (such as phosphorus, arsenic, other n-type dopant, or combinations thereof) having a doping concentration in a range from about 2×10¹⁹/cm³ to 3×10²¹/cm³. In some embodiments, the source/drain features 122N for n-type transistors may be respectively referred to as n-type features and n-type source/drain features.

In some embodiments, the source/drain features 122P may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 122P may be doped with p-type dopants (such as boron, indium, other p-type dopant, or combinations thereof) having a doping concentration in a range from about 1×10¹⁹/cm³ to 6×10²⁰/cm³. In some embodiments, the source/drain features 122P for p-type transistors may be respectively referred to as p-type source/drain features. It should be understood that the circuit cell 102′ also includes source/drain features 122N′ (including source/drain features 122N-1′ to 122N-5′) and source/drain features 122P′ (including source/drain features 122P-1′ to 122P-5′) with similar configurations.

Referring to FIGS. 1C to 1G, the semiconductor structure 100 further include contact etch stop layers (CESLs) 124 over the source/drain features 122N and 122P and an interlayer dielectric (ILD) layer 126 over the CESLs 124. In some embodiments, the CESLs 124 are also conformally formed on the top surfaces of the source/drain features 122P and 122N and the bottom surfaces of the source/drain features 122N, as shown in FIG. 1C. Furthermore, the CESLs 124 are conformally formed on sidewalls of the source/drain features 122P and 122N in Y-Z cross-sections, as shown in FIGS. 1E to 1G. In other words, the CESLs 124 wrap around the source/drain features 122P and 122N.

The ILD layer 126 is over and between the CESLs 124 to fill the space between the CESLs 124. The CESLs 124 include a material that is different than ILD layer 126. The CESLs 124 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The ILD layer 126 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD layer 126 may be formed by PECVD (plasma enhanced CVD), FCVD (flowable CVD), or other suitable methods.

As shown in FIGS. 1A to 1G, the semiconductor structure 100 further includes conductive walls 128 and 128′, a dielectric layer 130, and a dielectric structure 132. The conductive walls 128 and 128′ and the dielectric structure 132 extend lengthwise in the X-direction. The conductive walls 128 and 128′, the dielectric layer 130, and the dielectric structure 132 are between the CFETs C1 to C4 in the circuit cell 102 and the CFETs C1′ to C4′ in the circuit cell 102′ in the Y-direction, as shown in FIGS. 1A to 1G. More specifically, the conductive walls 128 and 128′ are between the gate structures 106-2 to 106-3 in the circuit cell 102 and the gate structures 106-2′ to 106-3′ in the circuit cell 102′ in the Y-direction, as shown in FIG. 1A. In some embodiments, the conductive wall 128 is adjacent to the CFETs C1 to C4 and disposed within the cell boundary CB of the circuit cell 102, and the conductive wall 128 is adjacent to the CFETs C1′ to C4′ and disposed within the cell boundary CB′ of the circuit cell 102′. The conductive wall 128 is used for a local connection of the circuit cell 102 and the conductive wall 128′ is used for a local connection of the circuit cell 102′, and the details are discussed below. In some embodiments, the conductive walls 128 and 128′ include conductive material, such as metal material. Therefore, the conductive walls 128 and 128′ may also be referred to as the conductive walls.

As shown in FIGS. 1A to 1F, the dielectric structure 132 is between and in contact with the conductive walls 128 and 128′ in the Y-direction. In some embodiments, the dielectric structure 132 lengthwise overlaps the cell boundary CB and the cell boundary CB′ (more specifically, the cell boundary line CBL). The dielectric structure 132 separates the conductive wall 128 from the conductive wall 128′ in the Y-direction, as shown in FIGS. 1A to 1F.

As shown in FIGS. 1A and 1B, the dielectric layer 130 wraps around the conductive walls 128 and 128′ and the dielectric structure 132 in the top view. In some aspects, the conductive walls 128 and 128′ and the dielectric structure 132 are within the dielectric layer 130. The dielectric layer 130 also overlaps the cell boundary CB and the cell boundary CB′ (more specifically, the cell boundary line CBL), as shown in FIGS. 1A and 1B. Furthermore, the dielectric layer 130 has a rolling pin shape in the top view, as shown in FIGS. 1A and 1B.

It is noted that the dielectric structure 132 separates the conductive walls 128 and 128′, and the dielectric structure 132 and the dielectric layer 130 are different features. Such structure of the conductive walls 128 and 128′, the dielectric layer 130, and the dielectric structure 132 is due to the conductive walls 128 and 128′ are formed from a conductive structure by cutting the conductive structure. Therefore, the dielectric structure 132 is formed to fill the space in the cut conductive structure, result in the conductive walls 128 and 128′ with the dielectric structure 132 in between. The details of the conductive walls 128 and 128′, the dielectric layer 130, and the dielectric structure 132 are discussed further below.

As shown in FIGS. 1A to 1G, the circuit cell 102 further includes conductive walls 134-1 and 134-2 (may be collectively referred to as conductive walls 134), a dielectric layer 136, and a dielectric structure 138. The conductive walls 134-1 and 134-2 and the dielectric structure 138 extend lengthwise in the X-direction. The conductive walls 134-1 and 134-2, the dielectric layer 136, and the dielectric structure 138 are adjacent to the CFETs C1 to C4 in the circuit cell 102 in the Y-direction, as shown in FIGS. 1A to 1G. In some embodiments, the conductive walls 134-1 and 134-2 and the dielectric structure 138 lengthwise overlap the cell boundary CB. The conductive walls 134-1 and 134-2 are electrically connected to a voltage source to supply power for the circuit cell 102, and the detail are discussed below. In some embodiments, the conductive walls 134-1 and 134-2 include conductive material, such as metal material. Therefore, the conductive walls 134-1 and 134-2 may also be referred to as the conductive walls. As shown in FIGS. 1A to 1F, the dielectric structure 138 is between and in contact with the conductive walls 134-1 and 134-2 in the X-direction. The dielectric structure 138 separates the conductive wall 134-1 from the conductive wall 134-2 in the X-direction, as shown in FIGS. 1A to 1G.

As shown in FIGS. 1A and 1B, the dielectric layer 136 wraps around the conductive walls 134-1 and 134-2 and the dielectric structure 138 in the top view. In some aspects, the conductive walls 134-1 and 134-2 and the dielectric structure 138 are within the dielectric layer 136. It is noted that the dielectric structure 138 separates the conductive walls 134-1 and 134-2, and the dielectric structure 138 and the dielectric layer 136 are different features. Such structure of the conductive walls 134-1 and 134-2, the dielectric layer 136, and the dielectric structure 138 is due to the conductive walls 134-1 and 134-2 are formed from a conductive structure by cutting the conductive structure. Therefore, the dielectric structure 138 is formed to fill the space in the cut conductive structure, result in the conductive walls 134-1 and 134-2 with the dielectric structure 138 in between. The details of the conductive walls 134-1 and 134-2, the dielectric layer 136, and the dielectric structure 138 are discussed below. It should be understood that the circuit cell 102′ also includes conductive walls 134-1′ and 134-2′ (may be collectively referred to as conductive walls 134′), a dielectric layer 136′, and a dielectric structure 138′ with similar configurations.

Referring to FIGS. 1A to 1G, the semiconductor structure 100 further includes dielectric layers 140 and 142 over the conductive walls 128 and 128′, the dielectric layer 130, the dielectric structure 132, the conductive walls 134 and 134′, the dielectric layers 136 and 136′, the dielectric structures 138 and 138′, the gate structures 106 and 106′, and the ILD layer 126. Specifically, the dielectric layer 140 is formed over and covers the conductive walls 128 and 128′, the dielectric layer 130, the dielectric structure 132, the conductive walls 134 and 134′, the dielectric layers 136 and 136′, the dielectric structures 138 and 138′, the gate structures 106 and 106′, and the ILD layer 126, and the dielectric layer 142 is formed over the dielectric layer 140. The dielectric layer 140 may serve as a contact etch stop layer and include a dielectric material similar to the material of the CESLs 124. In some embodiments, the dielectric layer 140 includes silicon nitride (Si₃N₄). The dielectric layer 140 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), or combinations thereof. In some embodiments, the dielectric layer 140 includes a dielectric material similar to the material of the ILD layer 126. The dielectric layers 140 and 142 may be formed by any suitable processes, such as CVD, PECVD, flowable CVD (FCVD), or combinations thereof.

Referring to FIGS. 1A to 1G, the semiconductor structure 100 further includes a dielectric layer 144. More specifically, the dielectric layer 144 is under and in contact with the conductive walls 128 and 128′, the dielectric layer 130, the dielectric structure 132, the conductive walls 134 and 134′, the dielectric layers 136 and 136′, the dielectric structures 138 and 138′, the gate structures 106 and 106′, and the ILD layer 126. In some embodiments, the dielectric layer 144 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), or combinations thereof. In some embodiments, the dielectric layer 144 includes a dielectric material similar to the material of the ILD layer 126. The dielectric layer 144 may be formed by any suitable processes, such as CVD, PECVD, flowable CVD (FCVD), or combinations thereof.

Referring to FIGS. 1A to 1G, the circuit cell 102 further includes source/drain contacts 146-1 to 146-5 (may be collectively referred to as source/drain contacts 146), source/drain contacts 148-1 to 148-5 (may be collectively referred to as source/drain contacts 148), and contact features 150-1 and 150-2 (may be collectively referred to as contact features 150). The source/drain contacts 146 are in the CESLs 124, the ILD layer 126, and the dielectric layers 140 and 142. The source/drain contacts 148 and the contact features 150 are in the dielectric layer 144. As shown in FIGS. 1A to 1G, the source/drain contacts 146 and 148 and contact features 150 extend lengthwise in the Y-direction. In some embodiments, the source/drain contacts 146 and the source/drain contacts 148 may be respectively referred to as front-side source/drain contacts and back-side source/drain contacts. The contact features 150 may be referred to as back-side contact features.

As shown in FIG. 1A, in the top view, the source/drain contact 146-1 is adjacent to the gate structure 106-1 (or is adjacent to the CFET C1) in the X-direction; the source/drain contact 146-2 is between the gate structures 104-1 and 106-2 (or between the CFETs C1 and C2) in the X-direction; the source/drain contact 146-3 is between the gate structures 106-2 and 106-3 (or between the CFETs C2 and C3) in the X-direction; the source/drain contact 146-4 is between the gate structures 106-3 and 106-4 (or between the CFETs C3 and C4) in the X-direction; and the source/drain contact 146-5 is adjacent to the gate structure 106-4 (or is adjacent to the CFET C4) in the X-direction.

Furthermore, the source/drain contacts 146 are over and in contact with the source/drain features 122N. In some embodiments, the source/drain contacts 146-1 and 146-5 are also over and in contact with the conductive walls 134, and the source/drain contact 146-3 is also over and in contact with the conductive wall 128. More specifically, as shown in FIGS. 1A to 1G, the source/drain contact 146-1 is over and electrically connected to the source/drain feature 122N-1 of the CFET C1 and the conductive wall 134-1; the source/drain contact 146-2 is over and electrically connected to the source/drain feature 122N-2 shared by the CFETs C1 and C2; the source/drain contact 146-3 is over and electrically connected to the source/drain feature 122N-3 shared by the CFETs C2 and C3 and the conductive wall 128; the source/drain contact 146-4 is over and electrically connected to the source/drain feature 122N-4 shared by the CFETs C3 and C4; and the source/drain contact 146-5 is over and electrically connected to the source/drain feature 122N-5 of the CFET C4 and the conductive wall 134-2.

As shown in FIG. 1B, in the top view, the source/drain contact 148-1 is adjacent to the gate structure 106-1 (or is adjacent to the CFET C1) in the X-direction; the source/drain contact 148-2 is between the gate structures 104-1 and 106-2 (or between the CFETs C1 and C2) in the X-direction; the source/drain contact 148-3 is between the gate structures 106-2 and 106-3 (or between the CFETs C2 and C3) in the X-direction; the source/drain contact 148-4 is between the gate structures 106-3 and 106-4 (or between the CFETs C3 and C4) in the X-direction; and the source/drain contact 148-5 is adjacent to the gate structure 106-4 (or is adjacent to the CFET C4) in the X-direction.

Furthermore, the source/drain contacts 148 are under and in contact with the source/drain features 122P. In some embodiments, the source/drain contact 148-4 is also under and in contact with the conductive wall 128. More specifically, as shown in FIGS. 1A to 1G, the source/drain contact 148-1 is under and electrically connected to the source/drain feature 122P-1 of the CFET C1; the source/drain contact 148-2 is under and electrically connected to the source/drain feature 122P-2 shared by the CFETs C1 and C2; the source/drain contact 148-3 is under and electrically connected to the source/drain feature 122P-3 shared by the CFETs C2 and C3; the source/drain contact 148-4 is under and electrically connected to the source/drain feature 122P-4 shared by the CFETs C3 and C4 and the conductive wall 128; and the source/drain contact 148-5 is under and electrically connected to the source/drain feature 122P-5 of the CFET C4.

In some embodiments, the contact feature 150-1 is under and in contact with the conductive wall 134-1 and the contact feature 150-2 is under and in contact with the conductive wall 134-2. More specifically, as shown in FIGS. 1A to 1G, the contact feature 150-1 is under and electrically connected to the conductive wall 134-1; and the contact feature 150-2 is under and electrically connected to the conductive wall 134-2. It should be understood that the circuit cell 102′ also includes source/drain contacts 146-1′ to 146-5′ (may be collectively referred to as source/drain contacts 146′), source/drain contacts 148-1′ to 148-5′ (may be collectively referred to as source/drain contacts 148′), and contact features 150-1′ and 150-2′ (may be collectively referred to as contact features 150′) with similar configurations.

The source/drain contacts 146 and 148 and the contact features 150 may each include a conductive material such as Al, Cu, W, Co, Ti, Ta, Ru, Rh, Ir, Pt, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contacts 146 and 148 and the contact features 150 may each include a single conductive material layer or multiple conductive layers.

Referring to FIGS. 1A to 1G, a front-side interconnection structure is over the semiconductor structure 100 and the circuit cell 102. The front-side interconnection structure includes a CESL 152, an ILD layer 154, a CESL 156, an ILD layer 158, metal conductors 160, and vias 162. The CESL 152 is over the dielectric layer 142 and source/drain contacts 146. The ILD layer 154 is over CESL 152. The CESL 156 is over the ILD layer 154 and the ILD layer 158 is over the CESL 156. The CESLs 152 and 156 includes a material similar to the material of the CESLs 124 discussed above. The ILD layers 154 and 158 includes a material similar to the material of the ILD layer 126 discussed above.

The metal conductors 160 are over the ILD layer 154 and pass through the CESL 156 and the ILD layer 158. The vias 162 pass through the ILD layer 154, the CESL 152, the dielectric layer 142, and dielectric layer 140 to electrically connect the gate structures 106 or the source/drain contacts 146 to the metal conductors 160, as shown in FIGS. 1C to 1G. It should be understood that the circuit cell 102′ also includes metal conductors 160′ and vias 162′ with similar configurations.

The materials of the vias 162 and the metal conductors 160 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

Referring to FIGS. 1A to 1G, a back-side interconnection structure is under the semiconductor structure 100 and the circuit cell 102. The back-side interconnection structure includes a CESL 166, an ILD layer 168, a CESL 170, an ILD layer 172, metal conductors 174 (including metal conductors 174-1 to 174-3), and vias 176 (including vias 176-1 to 176-6). The CESL 166 is under the dielectric layer 144, source/drain contacts 148, and the contact features 150. The ILD layer 168 is under the CESL 166. The CESL 170 is under the ILD layer 168 and the ILD layer 172 is under the CESL 170. The CESLs 166 and 170 includes a material similar to the material of the CESLs 124 discussed above. The ILD layers 168 and 172 includes a material similar to the material of the ILD layer 126 discussed above.

The metal conductors 174-1 to 174-3 are under ILD layer 168 and pass through CESL 170 and the ILD layer 172. The vias 176 pass through the CESL 166 and the ILD layer 168 to electrically connect the source/drain contacts 148 or the contact features 150 to the metal conductors 174, as shown in FIGS. 1C to 1G. Furthermore, the metal conductor 174-1 is electrically connected to a voltage source VSS to serve as the VSS line. As shown in FIGS. 1A to 1G, the conductive wall 134-1 and 134-2 are electrically connected to the metal conductor 174-1 through the contact features 150 and the vias 176. Therefore, the conductive walls 134-1 and 134-2 are also electrically connected to the voltage source VSS to supply power for the circuit cell 102 (more specifically, the source/drain features 122N-1 and 122N-5). The metal conductor 174-3 is electrically connected to a voltage source VDD to serve as the VDD line to supply power for the circuit cell 102. As shown in FIGS. 1A and 1B, the source/drain contact 150-2 is also electrically connected to the metal conductor 174-3 through the via 176-4. Therefore, the source/drain feature 122P-2 is also electrically connected to the voltage source VDD. The metal conductor 174-3 is also used to supply power for the circuit cell 102′.

As shown in FIGS. 1A to 1G, the source/drain features 122P-1, 122P-3, and 122P-5 are electrically connected to each other through the source/drain contact 150-1, 150-3, and 150-5, the vias 176-3, 176-5, 176-6, and the metal conductor 174-2. It should be understood that the circuit cell 102′ also includes metal conductors 174′ (including metal conductors 174-1′ to 174-2′), and vias 176′ (including vias 176-1′ to 176-6′) with similar configurations.

The materials of the via 176 and the metal conductors 174 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

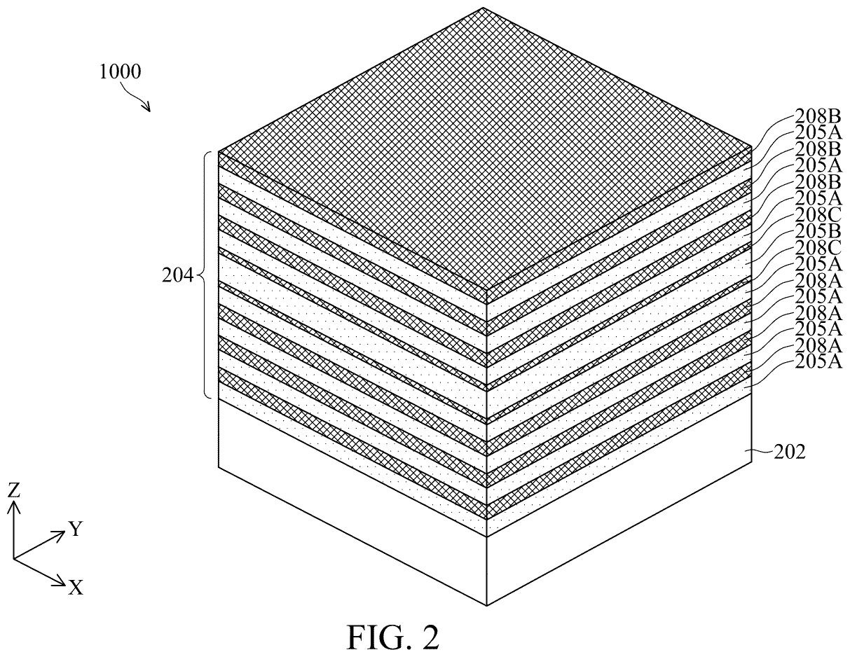

The details of the manufacturing method of the semiconductor structure 100 are discussed below. Referring to FIG. 2, a workpiece 1000 for the semiconductor structure 100 is provided. The workpiece 1000 includes a substrate 202 and a stack 204 over the substrate 202. In some embodiments, the substrate 202 contains a semiconductor material, such as bulk silicon (Si). In some other embodiments, the substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure or a germanium-on-insulator (GOI) structure. In some embodiments, the substrate 202 may include one or more well regions, such as n-type well regions doped with an n-type dopant (i.e., phosphorus (P) or arsenic (As)) or p-type well regions doped with a p-type dopant (i.e., boron (B)), for forming different types of devices. The doping the n-type wells and the p-type wells may be formed using ion implantation or thermal diffusion.

The stack 204 includes semiconductor layers 205 (including semiconductor layers 205A and a semiconductor layer 205B) and 208 (including semiconductor layers 208A, semiconductor layers 208B, and semiconductor layers 208C), and the semiconductor layers 205 and 208 are alternately stacked in the Z-direction. As shown in FIG. 2, a thickness of the semiconductor layer 205B is greater than a thickness of the semiconductor layers 205A and a thickness of the semiconductor layers 208.

Furthermore, a thickness of the semiconductor layers 208C is less than a thickness of the semiconductor layers 208A and 208B and a thickness of the semiconductor layers 205. In some embodiments, a thickness of the semiconductor layer 106B is in a range from about 5 nm to about 25 nm.

The semiconductor layers 205 and the semiconductor layers 208 may have different semiconductor compositions. In some embodiments, the semiconductor layers 208 may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, semiconductor layers 205 are formed of silicon germanium (SiGe) and the semiconductor layers 208 are formed of silicon (Si). In these embodiments, the additional germanium content in the semiconductor layers 205 allow selective removal or recess of the semiconductor layers 205 without substantial damages to the semiconductor layers 208, so that the semiconductor layers 205 are also referred to as sacrificial layers. The germanium concentration of the semiconductor layer 205B is greater than the germanium concentration of the semiconductor layers 205A.

In some embodiments, the semiconductor layers 205 and 208 are epitaxially grown over (on) the semiconductor substrate 202 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized. The semiconductor layers 205 and the semiconductor layers 208 are deposited alternatingly, one-after-another, to form the stack 204.

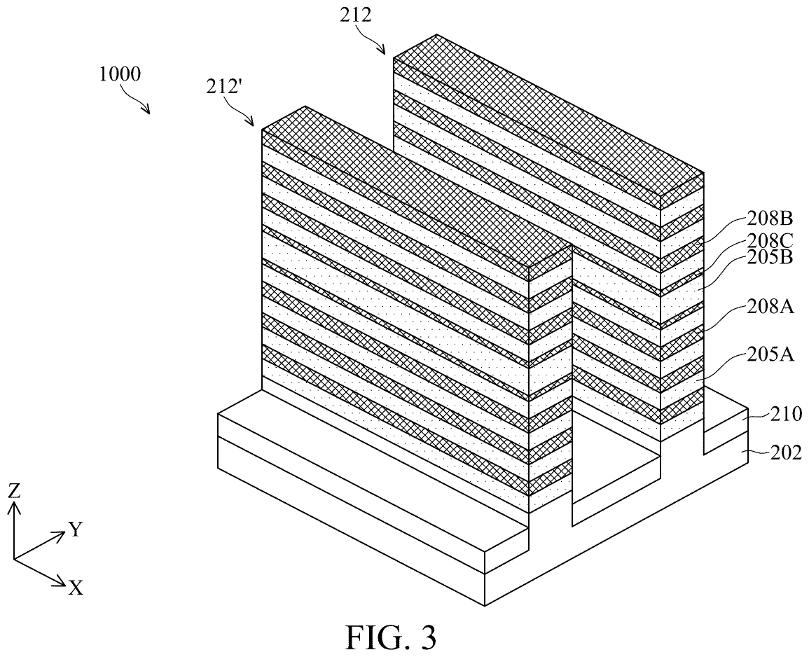

Referring to FIG. 3, the substrate 202 and the stack 204 are then patterned to form fins 212 and 212′ over the substrate 202. As shown in FIG. 3, each of the fins 212 and 212′ includes a base portion formed from a portion of the substrate 202 and a stack portion formed from the stack 204 over the base portion. The fins 212 and 212′ extend lengthwise in the X-direction and extend vertically in the Z-direction over the substrate 202. In some embodiments, the fins 212 and 212′ are respectively disposed in the active areas 104 and 104′ discussed above.

The fins 212 and 212′ may be patterned using suitable processes including double-patterning or multi-patterning processes. For example, in some embodiment, a material layer is formed over a substrate and patterned using a photolithography process. Spacers are formed alongside the patterned material layer using a self-aligned process. The material layer is then removed, and the remaining spacers, or mandrels, may then be used to pattern the fins 212 and 212′ by etching the stack 204 and the substrate 202. The etching process may include dry etching, wet etching, reactive ion etching (RIE), and/or other suitable processes.

Still referring to FIG. 3, after the fins 212 and 212′ are formed, the isolation structures 210 are formed over the substrate 202. In some embodiments, the isolation structures 210 extend in the X-direction (not shown) and is arranged with the fins 212 and 212′ in the Y-direction. In some other aspects, the isolation structures 210 are formed around the fins 212 and 212′. The isolation structures 210 may also be referred to as shallow trench isolation (STI) feature. In some embodiments, a dielectric material for the isolation structures 210 is first deposited over the workpiece 1000. In some embodiments, the dielectric material may include silicon oxide, silicon nitride, silicon oxynitride, fluorine-doped silicate glass (FSG), a low-k dielectric, combinations thereof, and/or other suitable materials. In various embodiments, the dielectric material may be deposited by a CVD, a subatmospheric CVD (SACVD), a flowable CVD (FCVD), an ALD, spin-on coating, and/or other suitable process. The deposited dielectric material is then thinned and planarized, for example by a chemical mechanical polishing (CMP) process. The planarized dielectric material is further recessed by a dry etching process, a wet etching process, and/or a combination thereof to form the isolation structures 210. As shown in FIG. 3, the stack portions of the fins 212 and 212′ rise above the isolation structures 210 while the base portions of the fins 212 and 212′ are surrounded by the isolation structures 210. In other words, a top surface of the substrate 202 is higher than top surfaces of the isolation structures 210.

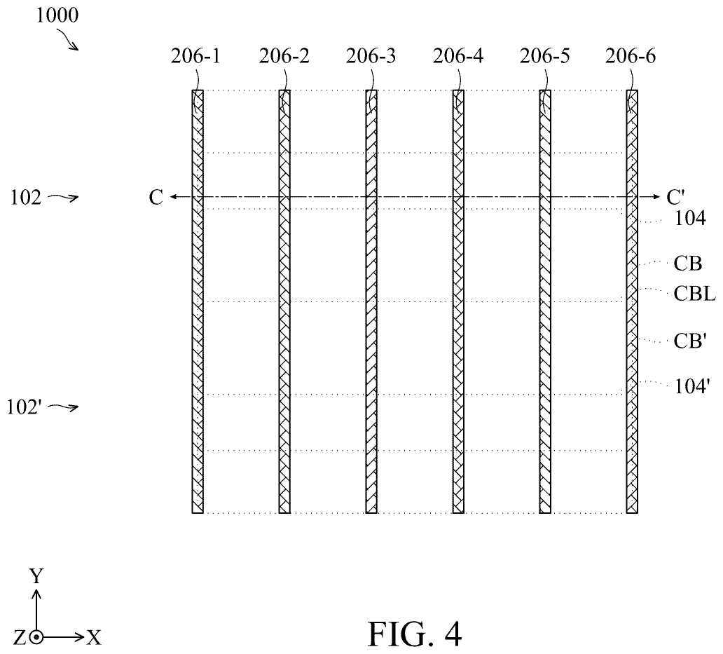

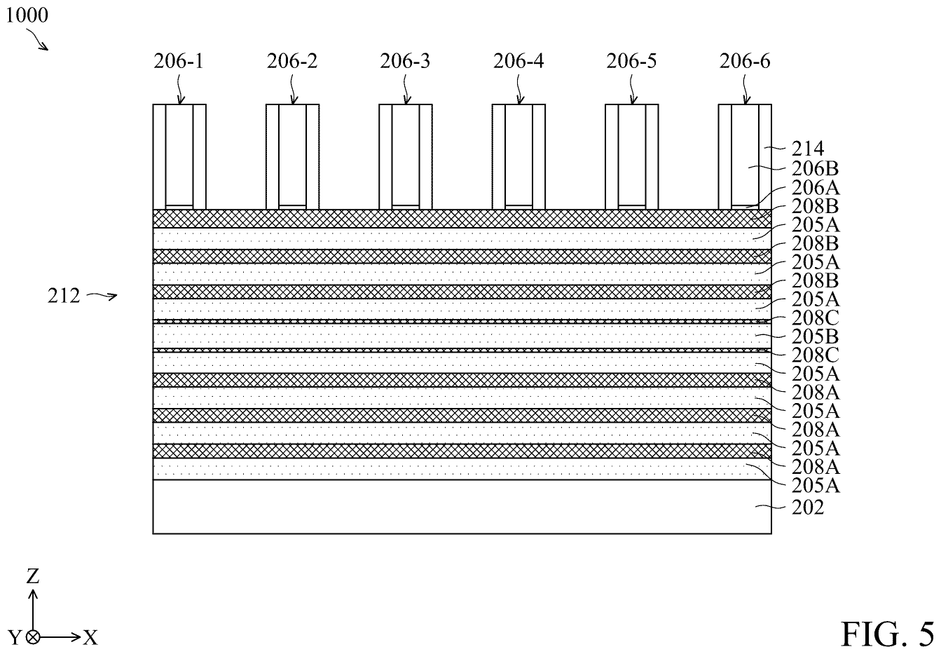

FIG. 4 is a top view (or a layout) of the workpiece 1000 at various fabrication stages, in accordance with some embodiments of the present disclosure. FIG. 5 is an X-Z cross-sectional view of the workpiece 1000 at various fabrication stages along a line C-C′ in FIG. 4, in accordance with some embodiments of the present disclosure. Referring to FIGS. 4 and 5, dummy gate structures 206 (including dummy gate structures 206-1 to 206-6) may be formed over the fins 212 and 212′ in the active areas 104 and 104′ and over the isolation structures 210 (not shown). The dummy gate structure 206 may be configured to extend along the Y-direction and wrap around a top surface and side surfaces of the fins 212 and 212′. In some embodiments, to form the dummy gate structure 206, a dummy interfacial material of a dummy interfacial layer 206A is first formed over the fins 212 and 212′ and over the isolation structures 210. In some embodiments, the dummy interfacial layer 206A may include, for example, a dielectric material such as a nitride (e.g., silicon nitride, silicon oxynitride), a carbide (e.g., silicon carbide), an oxide (e.g., silicon oxide), or some other suitable material. Then, in some embodiments, a dummy gate material of a dummy gate electrode 206B is formed over the dummy interfacial material. The dummy gate material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or combinations thereof. The dummy gate material and/or the dummy interfacial material may be formed by way of a thermal oxidation process and/or a deposition process (e.g., PVD, CVD, PECVD, and ALD). After the formation of the dummy gate material and the dummy interfacial material, lithography and etching processes may be performed to remove portions of the dummy gate material and the dummy interfacial material, thereby forming the dummy gate structures 206 with dummy gate electrode 206B and the dummy interfacial layer 206A. The dummy gate structures 206 may undergo a gate replacement process through subsequent processing to form metal gates, such as a high-k metal gate, as discussed in greater detail below.

Still referring to FIG. 5, after the formation of the dummy gate structures 206, the gate spacers 214 (will be divided into the gate spacers 118 and 118′ discussed above) are formed on sidewalls of the dummy gate structures 206, over a top surface of the fins 212 and 212′. The gate spacers 214 may include multiple dielectric materials selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. The gate spacers 214 may include a single layer or a multi-layer structure.

In some embodiments, the gate spacers 214 may be formed by depositing a spacer layer (containing the dielectric material) over the isolation structures 210, the fins 212 and 212′, and dummy gate structures 206, followed by an anisotropic etching process to remove top portions of the spacer layer from the top surfaces of the isolation structures 210, the fins 212 and 212′, and dummy gate structures 206. After the etching process, portions of the spacer layer on the sidewall surfaces of the fins 212 and 212′ and the dummy gate structures 206 substantially remain and become the gate spacers 214. In some embodiments, the anisotropic etching process is a dry (e.g., plasma) etching process. Additionally or alternatively, the formation of the gate spacers 214 may also involve chemical oxidation, thermal oxidation, ALD, CVD, and/or other suitable methods. The gate spacers 214 may also be interchangeably referred to as the top spacers.

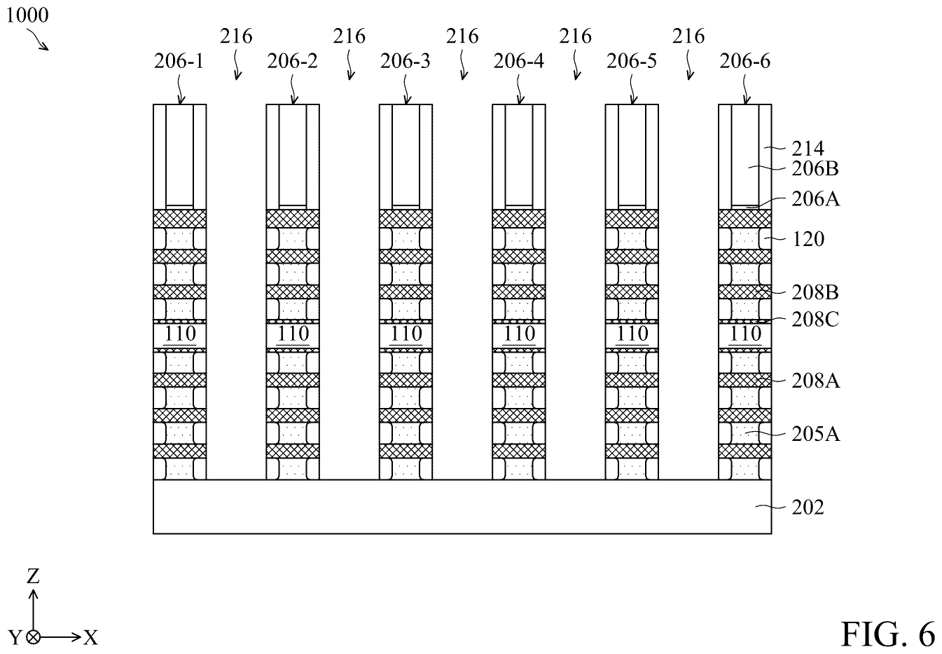

Referring to FIG. 6, after the formation of the gate spacers 214, the fins 212 and 212′ are recessed to form source/drain trenches 216 in the fins 212 and 212′ (or passing through the semiconductor layers 205 and 208). Specifically, the source/drain trenches 216 may be formed by performing one or more etching processes to remove portions of the semiconductor layers 205, the semiconductor layers 208, and the substrate 202 that do not vertically overlap or be covered by the dummy gate structures 206 and the gate spacers 214. In some embodiments, a single etchant may be used to remove the semiconductor layers 205 and the semiconductor layers 208, whereas in other embodiments, multiple etchants may be used to perform the etching process.

Still referring to FIG. 6, after the formation of the source/drain trenches 216, the inner spacers 120 discussed above are formed. More specifically, after the formation of the source/drain trenches 216, side portions of the semiconductor layers 205A are removed via a selective etching process, the semiconductor layer 205B is not removed. The selective etching process is performed that selectively etches the side portions of the semiconductor layers 205A below the gate spacers 214 through the source/drain trenches 216, with minimal (or no) etching of the semiconductor layer 205B and the semiconductor layers 208, such that gaps are formed between the semiconductor layers 208 as well as between the semiconductor layers 208 and the substrate 202, below the gate spacers 214. The etching process is configured to laterally etch (e.g., along the X-direction) the semiconductor layers 205A below the gate spacers 214. The selective etching process is a dry etching process, a wet etching process, other suitable etching process, or combinations thereof.

After the formation of the gaps discussed above, inner spacers 120 (furthermore, the inner spacers 120′) discussed above are formed to fill the gaps. In some embodiments, sidewalls of the inner spacers 120 are aligned to sidewalls of the gate spacers 214 and the semiconductor layers 208, as shown in FIG. 6. In order to form the inner spacers 120, a deposition process forms a spacer layer into the source/drain trenches 216 and the gaps discussed above, such as CVD, PVD, ALD, HDPCVD, MOCVD, RPCVD, PECVD, LPCVD, ALCVD, APCVD, other suitable methods, or combinations thereof. The spacer layer partially (and, in some embodiments, completely) fills the source/drain trenches 216. The deposition process is configured to ensure that the spacer layer fills the gaps between the semiconductor layers 208 as well as between the semiconductor layer 208 and the substrate 202 under the gate spacers 214. An etching process is then performed that selectively etches the spacer layer to form inner spacers 120 (as shown in FIG. 6) with minimal (to no) etching of the semiconductor layer 208, the substrate 202, the dummy gate structures 206, and the gate spacers 214. The spacer layer (and thus inner spacers 120 and 120′) includes a material that is different than a material of the semiconductor layers 208 and a material of the gate spacers 214 to achieve desired etching selectivity during the etching process. As discussed above, in some embodiments, the inner spacers 120 and 120′ include a dielectric material selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof.

Still referring to FIG. 6, after the formation of the inner spacers 120, the semiconductor layers 205B are replaced with the dielectric layers 110 (furthermore, the dielectric layers 110′) discussed above. More specifically, after the formation of the inner spacers 120, the semiconductor layer 205B are removed via a selective etching process. The selective etching process is performed that selectively etches the semiconductor layer 205B below the dummy gate structures 206 and the gate spacers 214 through the source/drain trenches 216, with minimal (or no) etching of the semiconductor layers 208, such that gaps are formed between the semiconductor layers 208 (more specifically, between the semiconductor layers 208C), below the dummy gate structures 206 and the gate spacers 214. The etching process is configured to laterally etch (e.g., along the X-direction) the semiconductor layer 205B below the dummy gate structures 206 and the gate spacers 214. The selective etching process is a dry etching process, a wet etching process, other suitable etching process, or combinations thereof.

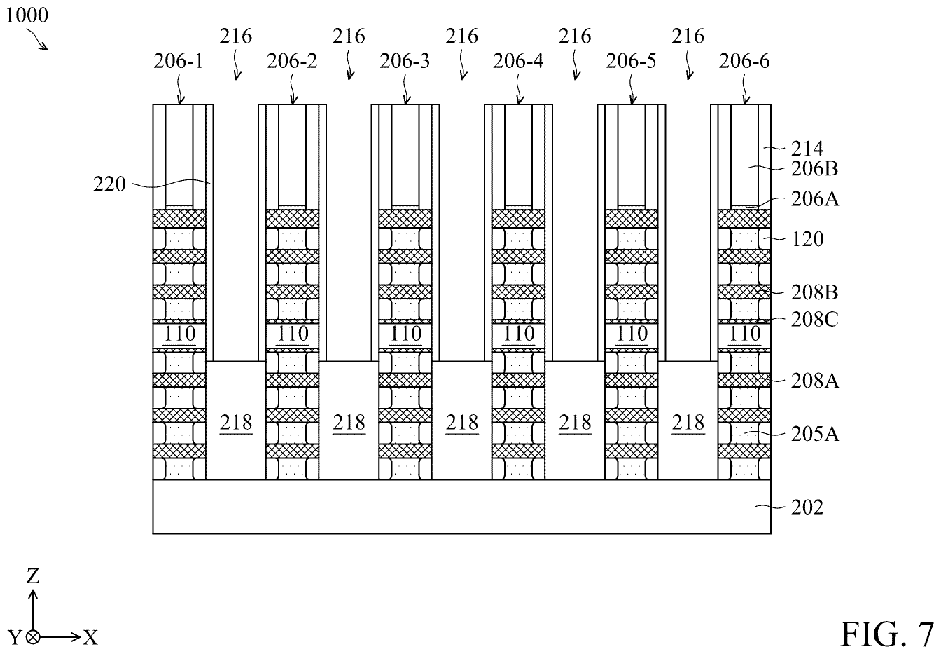

After the formation of the gaps discussed above, dielectric layers 110 are formed to fill the gaps. In some embodiments, sidewalls of the dielectric layers 110 are aligned to sidewalls of the gate spacers 214, the inner spacers 120, and the semiconductor layers 208, as shown in FIG. 6. In order to form the dielectric layers 110, a deposition process forms a dielectric material into the source/drain trenches 216 and the gaps, such as CVD, PVD, ALD, HDPCVD, MOCVD, RPCVD, PECVD, LPCVD, ALCVD, APCVD, other suitable methods, or combinations thereof. The dielectric material partially (and, in some embodiments, completely) fills the source/drain trenches 216. The deposition process is configured to ensure that the dielectric material fills the gaps between the semiconductor layers 208 (more specifically, between the semiconductor layers 208C) under the dummy gate structures 206 and the gate spacers 214. An etching process is then performed that selectively etches the dielectric material to form the dielectric layers 110 (as shown in FIG. 7) with minimal (to no) etching of the semiconductor layer 208, the substrate 202, the dummy gate structures 206, the gate spacers 214, and the inner spacers 120. In some embodiments, the dielectric layers 110 are between and in contact with the semiconductor layers 208C. Furthermore, the dielectric layers 110 are also between the semiconductor layers 208A and the semiconductor layers 208C, as shown in FIG. 6. The dielectric layers 110 are thicker than the semiconductor layers 208A and 208B. In some embodiments, the dielectric material of dielectric layers 110 includes silicon, oxygen, carbon, nitrogen, other suitable material, or combinations thereof (for example, silicon oxide (SiO₂), silicon nitride (SiN), silicon oxynitride (SiON), silicon oxycarbide (SiOC), silicon carbon nitride (SiCN), silicon oxycarbon nitride (SiOCN)).

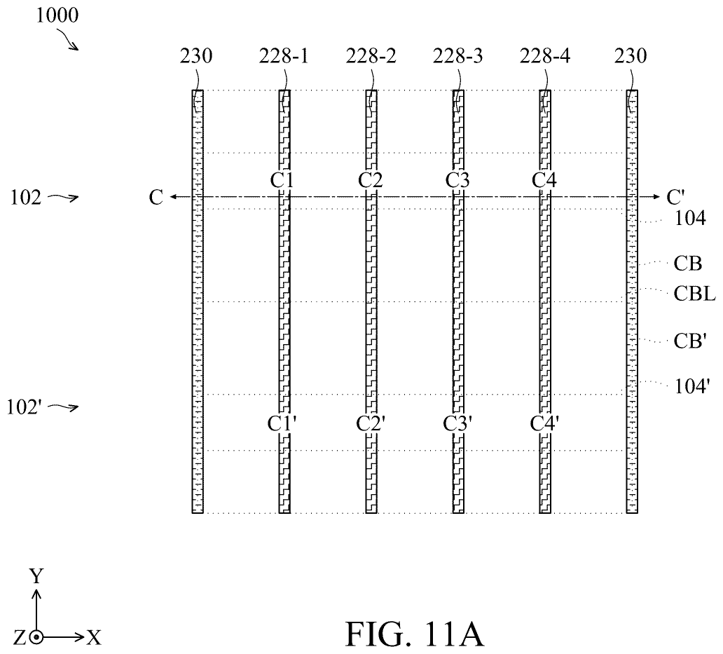

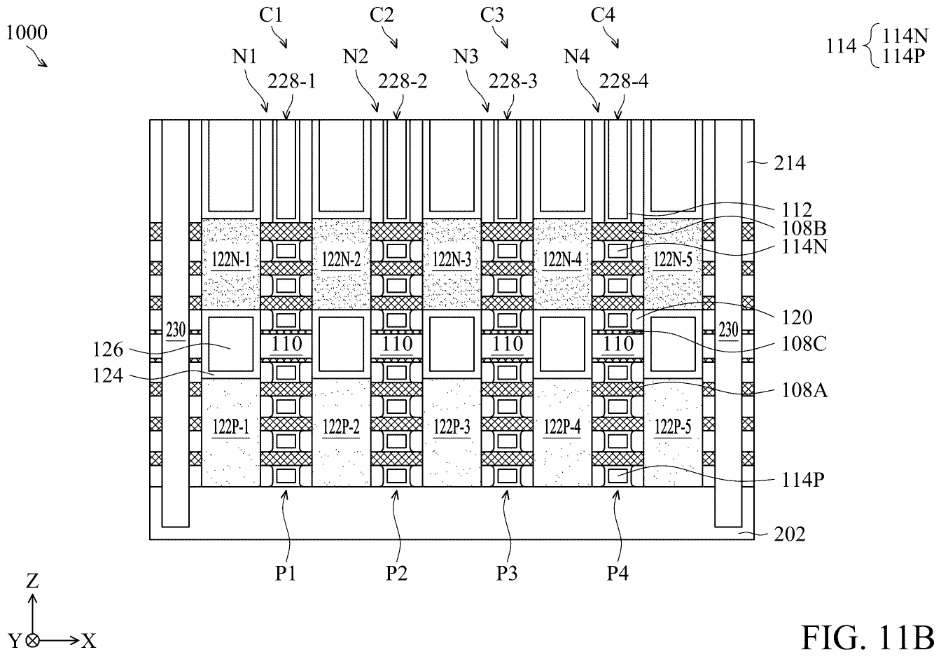

Referring to FIG. 7, polymer layers 218 and dielectric layers 220 are formed in the source/drain trenches 216. More specifically, the polymer layers 218 are first formed in lower parts of the source/drain trenches 216 to cover a bottom surface of the substrate 202 and the sidewalls of the semiconductor layers 208A (which are used for the PFET of the CFET, such as the p-type transistors P1 to P4 of the CFETs C1 to C4 shown in FIGS. 1C and 11B) and the inner spacers 120 (which are between the semiconductor layers 208A). In some embodiments, top surfaces of the polymer layers 218 are lower than the dielectric layers 110 and the semiconductor layers 208B. After the formation of the polymer layers 218, the dielectric layers 220 are formed over the polymer layers 218 and on the sidewalls of the semiconductor layers 208B, the semiconductor layers 208B (which are used for the NFET of the CFET, such as the n-type transistors N1 to N4 of the CFETs C1 to C4 shown in FIGS. 1C and 11B), the gate spacers 214, and the inner spacers 120 (which are between the semiconductor layers 208B). The polymer layers 218 are formed of fluorine-containing polymer and its molecular structure includes silicon (Si), carbon (C), nitrogen (N), or fluorine (F). In one example, the polymer layers 218 include fluorinated silicone or fluorinated polysilane. The polymer layers 218 may be deposited using CVD, flowable CVD (FCVD), or spin-on coating. The dielectric layers 220 may include aluminum oxide (Al₂O₃).

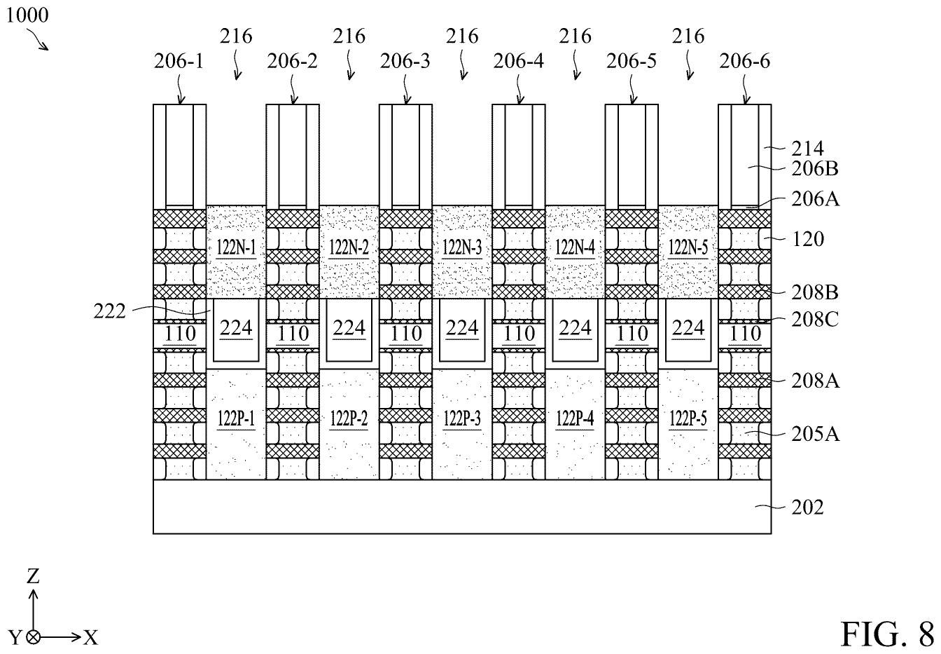

Referring to FIG. 8, the polymer layers 218 are removed via a selective etching process and the source/drain features 122P-1 to 122P-5 (furthermore, the source/drain features 122P-1′ to 122P-5′) discussed above are formed in the source/drain trenches 216. Specifically, the selective etching process is performed that selectively etches the polymer layers 218 below the dielectric layers 220 through the source/drain trenches 216, with minimal (or no) etching of the semiconductor layers 208A, the substrate 202, and the inner spacers 120. The selective etching process is a dry etching process, a wet etching process, other suitable etching process, or combinations thereof.

After the removal of the polymer layers 218, the source/drain features 122P (furthermore, the source/drain features 122P′) discussed above are formed in the lower parts of the source/drain trenches 216 and below the dielectric layers 220. The source/drain features 122P are also formed on opposite sides of the dummy gate structure 206 in the X-direction. The source/drain features 122P are connected to and in contact with the semiconductor layers 208A (and thus the semiconductor layers 108A discussed above). In some aspects, the semiconductor layers 208A connect one source/drain feature 122P to the other source/drain feature 122P.

In some embodiments, the source/drain features 122P may have top surfaces that extend higher than top surfaces of the topmost semiconductor layers 208A (e.g., in the Z-direction). In other embodiments, the top surfaces of the source/drain features 122P and the top surfaces of the topmost semiconductor layers 208A are substantially coplanar. Furthermore, top surfaces of the source/drain features 122P are lower than the bottom surfaces of the dielectric layers 220, the dielectric layers 110, and the semiconductor layers 208B.

One or more epitaxy processes may be employed to grow the source/drain features 122P. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. The source/drain features 122P are grown from the substrate 202 and the semiconductor layers 208A rather than the semiconductor layers 208B and 208C due to the dielectric layers 220 cover the sidewalls of the semiconductor layers 208B and 208C.

The source/drain features 122P may include any suitable semiconductor materials. For example, the source/drain features 122P used for the PFETs of the CFETs (e.g., the p-type transistors P1 to P4 of the CFETs C1 to C4 shown in FIGS. 1C and 11B) may include epitaxially-grown material selected from a group consisting of boron-doped SiGe, boron-doped SiGeC, boron-doped Ge, boron-doped Si, boron and carbon doped SiGe, or a combination thereof. The source/drain features 122P may also be referred to as source/drain, or source/drain regions. In some embodiments, the source/drain features 122P may be referred to as p-type source/drain features. The source/drain features 122P may be doped in-situ or ex-situ. One or more annealing processes may be performed to activate the dopants in the source/drain features 122P. The annealing processes may include rapid thermal annealing (RTA) and/or laser annealing processes.

Still referring to FIG. 8, after the formation of the source/drain features 122P, the dielectric layers 220 are removed via a selective etching process, and then dielectric layers 222 and polymer layers 224 are formed in the source/drain trenches 216. Specifically, the selective etching process is performed that selectively etches the dielectric layers 220 over the source/drain features 122P through the source/drain trenches 216, with minimal (or no) etching of the dielectric layers 110, the semiconductor layers 208B, the semiconductor layers 208C, the gate spacers 214, and the inner spacers 120. The selective etching process is a dry etching process, a wet etching process, other suitable etching process, or combinations thereof.

After the removal of the dielectric layers 220, the dielectric layers 222 are first conformally formed on the top surfaces of the source/drain features 122P and on the sidewalls of the semiconductor layers 208B and the dielectric layers 110. After the formation of the dielectric layers 222, the polymer layers 224 are then formed over the dielectric layers 222. In some embodiments, top surfaces of the dielectric layers 222 and the polymer layers 224 are lower than the semiconductor layers 208B. The dielectric layers 222 may include aluminum oxide (Al₂O₃). The polymer layers 224 are formed of fluorine-containing polymer and its molecular structure includes silicon (Si), carbon (C), nitrogen (N), or fluorine (F). In one example, the polymer layers 224 include fluorinated silicone or fluorinated polysilane. The polymer layers 224 may be deposited using CVD, flowable CVD (FCVD), or spin-on coating.

Still referring to FIG. 8, after the formation of the dielectric layers 222 and the polymer layers 224, source/drain features 122N-1 to 122N-5 (furthermore, the source/drain features 122N-1′ to 122N-5′) discussed above are formed in the source/drain trenches 216. Specifically, the source/drain features 122N are over the dielectric layers 222, the polymer layers 224, and the source/drain features 122P. The source/drain features 122N are also formed on opposite sides of the dummy gate structures 206 in the X-direction. Furthermore, the source/drain features 122N-1 to 122N-5 are directly over the source/drain features 122P-1 to 122P-5, respectively. The source/drain features 122N are connected to and in contact with the semiconductor layers 208B (and thus the semiconductor layers 108B discussed above). In some aspects, the semiconductor layers 208B connect one source/drain feature 122N to the other source/drain feature 122N.

In some embodiments, the source/drain features 122N may have top surfaces that extend higher than top surfaces of the topmost semiconductor layers 208B (e.g., in the Z-direction). In other embodiments, the top surfaces of the source/drain features 122N and the top surfaces of the topmost semiconductor layers 208B are substantially coplanar. Furthermore, the bottom surfaces of the source/drain features 122N are higher than the top surfaces of the dielectric layers 110 and the semiconductor layers 208C. In some embodiments, bottom surfaces of the source/drain features 122N are lower than the bottom surfaces of the bottommost semiconductor layers 208B. In other embodiments, the bottom surfaces of the source/drain features 122N and the bottom surfaces of the bottommost semiconductor layers 208B are substantially coplanar.

One or more epitaxy processes may be employed to grow the source/drain features 122N. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. The source/drain features 122N are grown from the semiconductor layers 208B rather than the semiconductor layers 208C due to the dielectric layers 222 cover the sidewalls of the semiconductor layers 208C.

The source/drain features 122N may include any suitable semiconductor materials. For example, the source/drain features 122N used for the NFETs of the CFETs (e.g., the n-type transistors N1 to N4 of the CFETs C1 to C4 shown in FIGS. 1C and 11B) may include epitaxially-grown material selected from a group consisting of SiP, SiC, SiPC, SiAs, Si, or a combination thereof. The source/drain features 122N may also be referred to as source/drain, or source/drain regions. In some embodiments, the source/drain features 122N may be referred to as n-type source/drain features. The source/drain features 122N may be doped in-situ or ex-situ. One or more annealing processes may be performed to activate the dopants in the source/drain features 122N. The annealing processes may include rapid thermal annealing (RTA) and/or laser annealing processes.

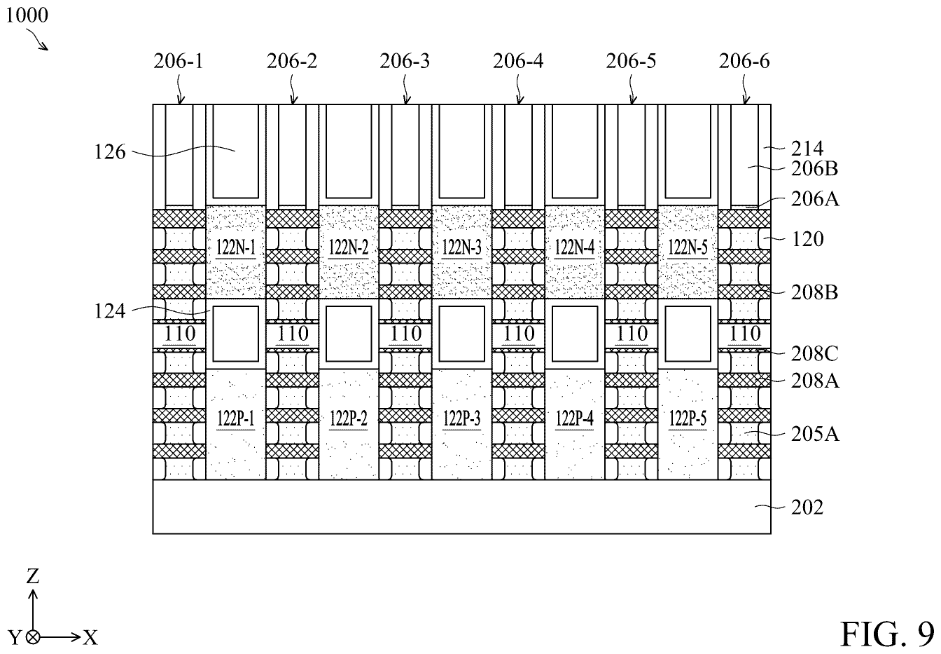

Referring to FIG. 9, after the formation of the source/drain features 122N, the dielectric layers 222 and the polymer layers 224 are removed via a selective etching process, and then the CESLs 124 and the ILD layer 126 discussed above are formed in the source/drain trenches 216. Specifically, the selective etching process is performed that selectively etches the dielectric layers 222 and the polymer layers 224 in the source/drain trenches 216, with minimal (or no) etching of the dielectric layers 110, the semiconductor layers 208C, and the source/drain features 122P and 122N. The selective etching process is a dry etching process, a wet etching process, other suitable etching process, or combinations thereof.

After the removal of the dielectric layers 222 and the polymer layers 224, the CESLs 124 over the source/drain features 122P and 122N and the ILD layer 126 over the CESLs 124 are formed to fill the space between the gate spacers 214 and in the source/drain trenches 216. Specifically, the CESLs 124 are conformally formed on the sidewalls of the gate spacers 214, the inner spacers 120, the dielectric layers 110, and the semiconductor layers 208C. In some embodiments, the CESLs 124 are also conformally formed on the top surfaces of the source/drain features 122P and 122N and the bottom surface of the source/drain features 122N, as shown in FIG. 9. Furthermore, the CESLs 124 are conformally formed on sidewalls of the source/drain features 122P and 122N in a Y-Z cross-section. In other words, the CESLs 124 wrap around the source/drain features 122P and 122N. The ILD layer 126 is formed over and between the CESLs 124 to fill the space between the CESLs 124, between the gate spacers 214 and in the source/drain trenches 216.

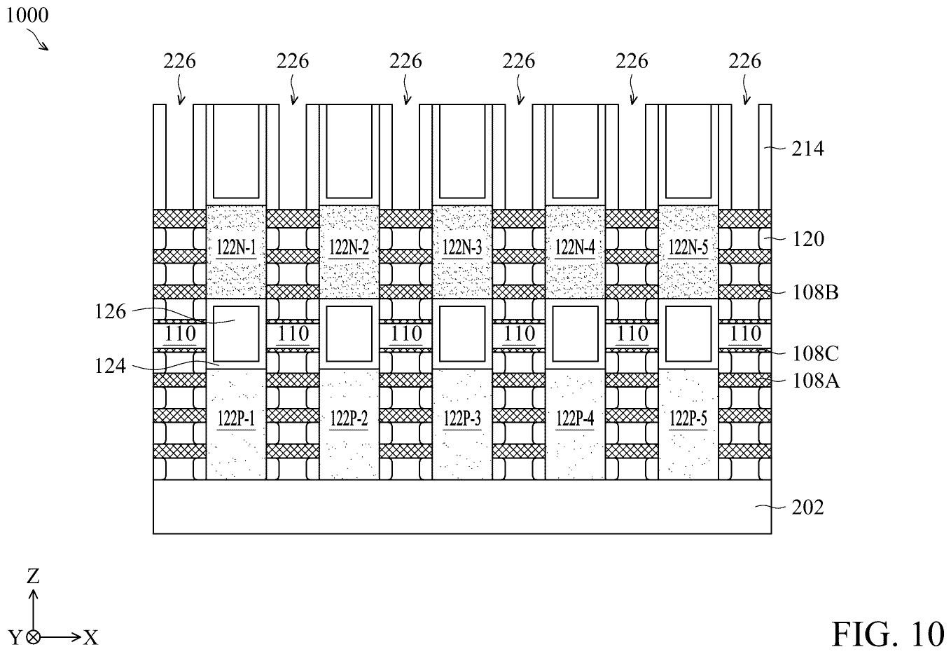

Referring to FIG. 10, the dummy gate structures 206 are selectively removed through any suitable lithography and etching processes. In some embodiments, the lithography process may include forming a photoresist layer (resist), exposing the resist to a pattern, performing a post-exposure bake process, and developing the resist to form a masking element, which exposes a region including the dummy gate structures 206. Then, the dummy gate structures 206 are selectively etched through the masking element. The gate spacers 214 may be used as the masking element or a part thereof. Etch selectivity may be achieved by selecting the appropriate etching chemicals, and the dummy gate structures 206 may be removed without substantially affecting the CESLs 124 and the ILD layer 126. The removal of the dummy gate structures 206 creates gate trenches 226. The gate trenches 226 expose the top surfaces of the topmost semiconductor layers 208B that underlies the dummy gate structures 206.

Still referring to FIG. 10, the semiconductor layers 205A of the fins 212 and 212′ are selectively removed through the gate trenches 226, using a wet or dry etching process for example, so that the semiconductor layers 208A, 208B, and 208C are exposed in the gate trench 226 to form the semiconductor layers 108A, 108B, and 108C (furthermore, the semiconductor layers 108A′, 108B′, and 108C′) discussed above. In some embodiments, the semiconductor layers 108A and 108B may be referred to as nanostructures. Specifically, the semiconductor layers 108A are stacked over each other in the Z-direction, and the semiconductor layers 108B are directly over the semiconductor layers 108A and are stacked over each other in the Z-direction. Such a process may also be referred to as a wire release process, a nanowire release process, a nanosheet release process, a nanowire formation process, a nanosheet formation process, or a wire formation process. In some embodiments, the removal of the semiconductor layers 205A causes the exposed semiconductor layers 108A or 108B to be spaced apart from each other in the vertical direction (e.g., in the Z-direction). The exposed semiconductor layers 108A and 108B extend longitudinally in the horizontal direction (e.g., in the X-direction). Furthermore, each of the semiconductor layers 108A and 108A connects one source/drain feature 122P to another source/drain feature 122P, and each of the semiconductor layers 108B connects one source/drain feature 122N to another source/drain feature 122N.

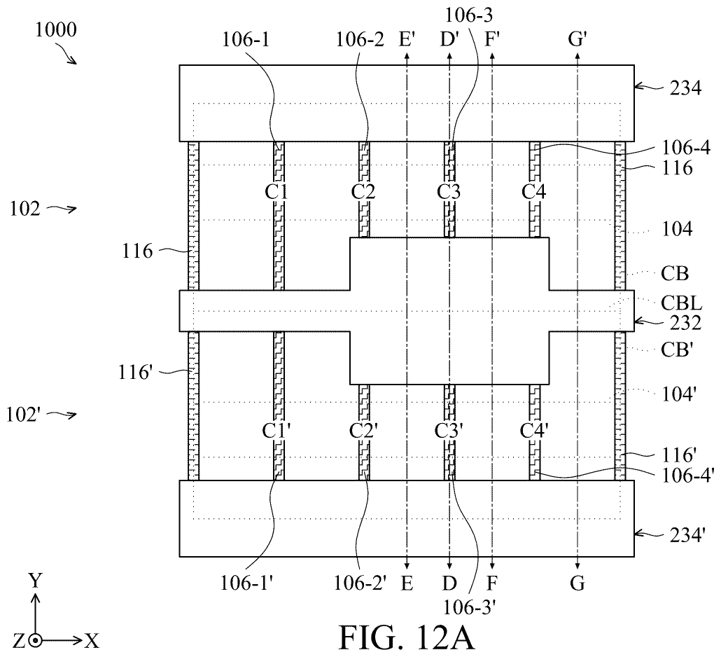

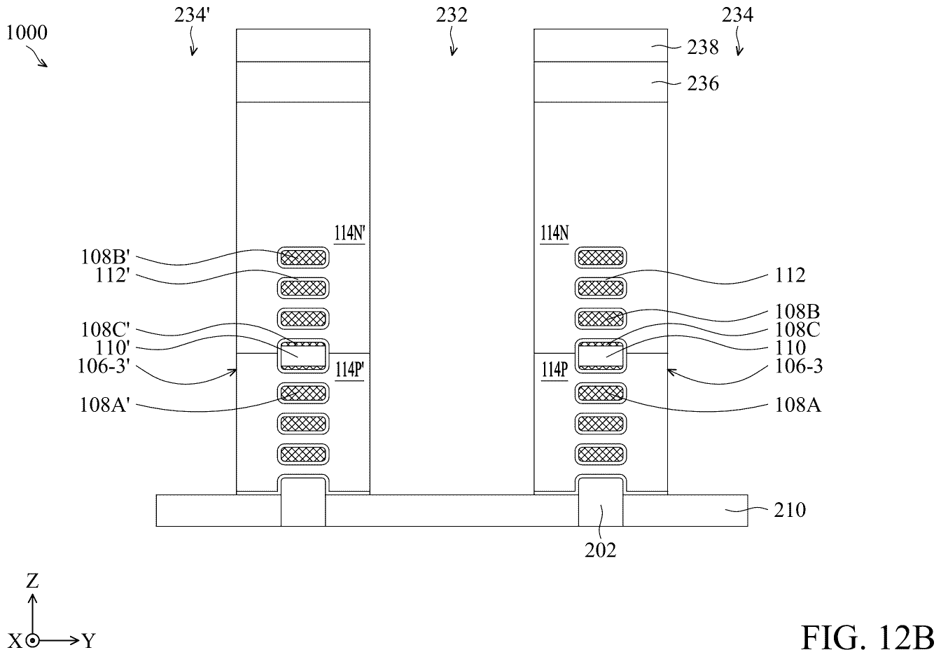

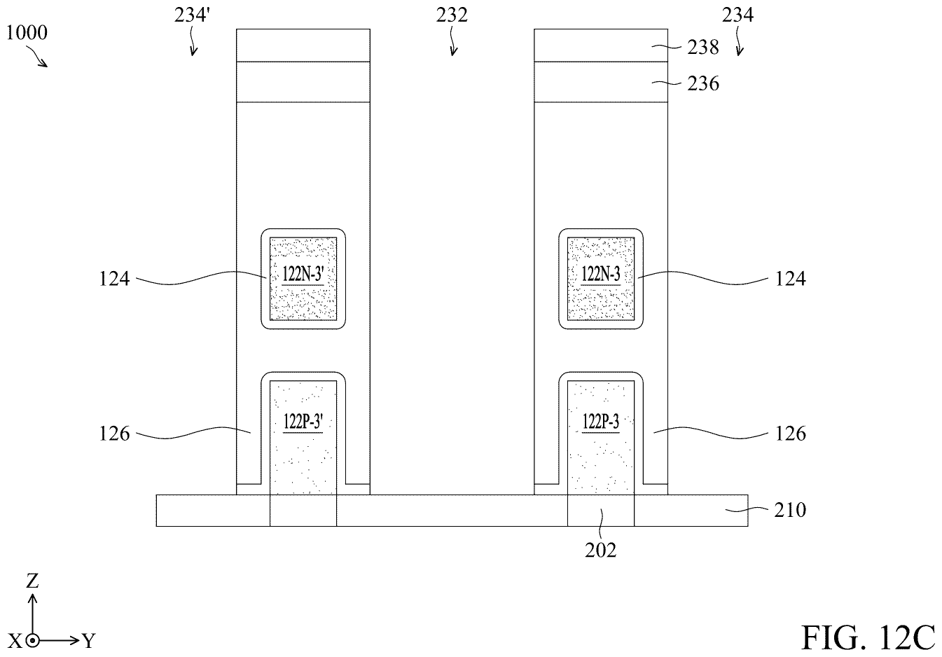

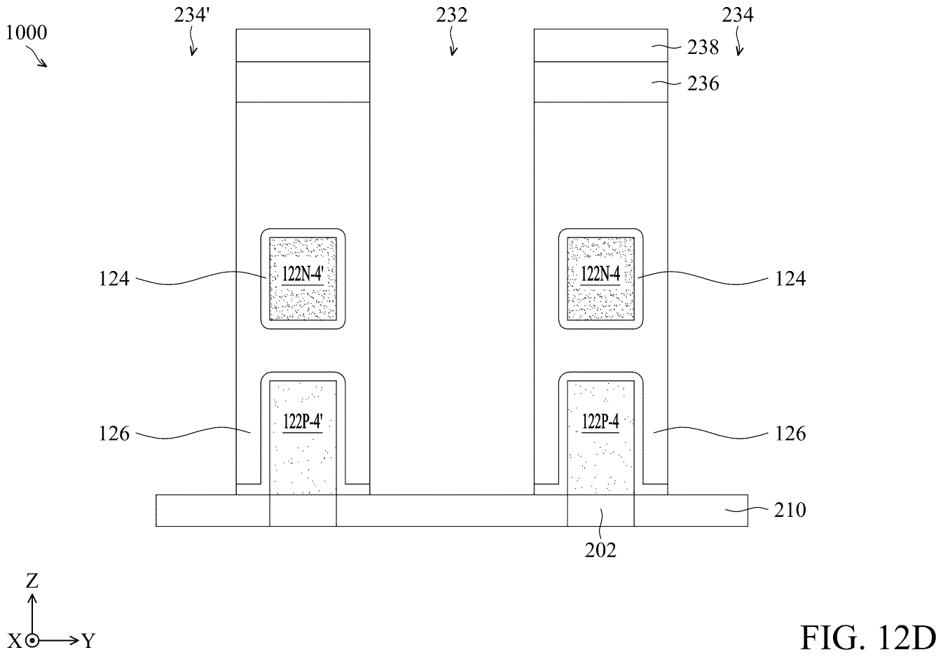

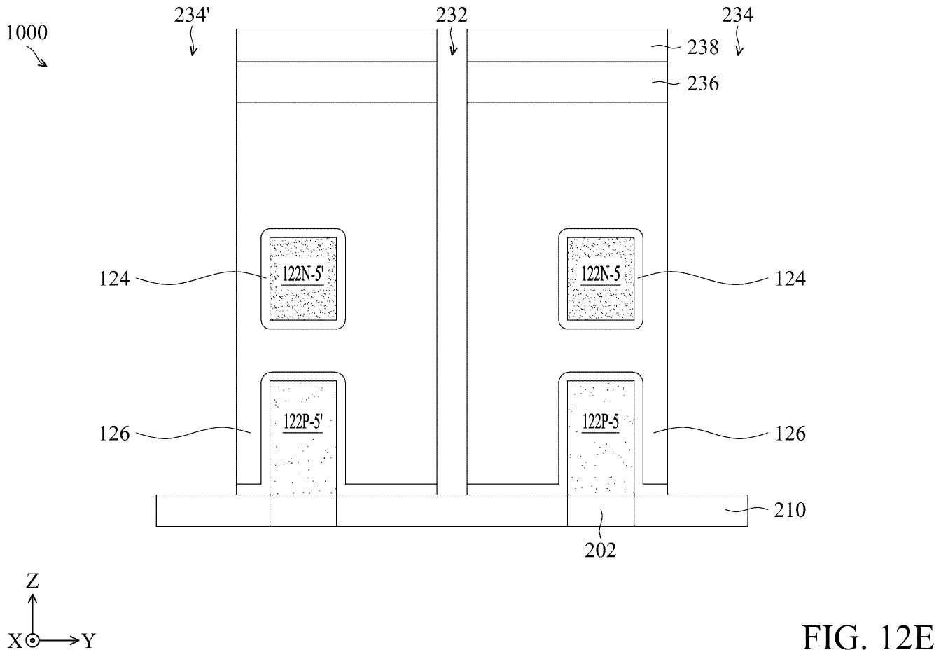

Referring to FIGS. 11A and 11B, gate structures are formed in the gate trenches 226 to wrap around the semiconductor layers 108A and 108B, and then some of the gate structures are replaced with dielectric structures 230. As such, gate structures 228-1 to 228-4 (may be collectively referred to as gate structures 228) and the dielectric structures 230 replace the dummy gate structures 206 and the semiconductor layers 205A. As shown in FIGS. 11A and 11B, the source/drain features 122N are on opposite sides of the gate structure 228 in the X-direction, and the source/drain features 122P are on opposite sides of the gate structure 228 in the X-direction. The gate structures 228 each includes the gate dielectric layer 112 and the gate electrode layer 114 (including the gate electrode layers 114P and 114N) discussed above. In some embodiments, the gate dielectric layers 112 are formed to wrap around the semiconductor layers 108A and 108B. Additionally, the gate dielectric layers 112 are also formed on the sidewalls of the inner spacers 120 and the gate spacers 214, as well as over the top surfaces of the isolation structures 210 (shown in FIG. 12B).

In some embodiments, the gate structures 228 may further include interfacial layers to wrap around the exposed semiconductor layers 108A and 108B before the formation of the gate dielectric layer 112, so that the gate dielectric layers 112 are separated from semiconductor layers 108A and 108B by the interfacial layer. The gate electrode layers 114 are formed to fill the remaining spaces of the gate trenches 226, and over the gate dielectric layers 112 in such a way that the gate electrode layers 114 wrap around the semiconductor layers 108A and 108B, the gate dielectric layer 112, and the interfacial layers (if present). The gate electrode layers 114 each may include a single layer or alternatively a multi-layer structure. In some embodiments, the gate electrode layers 114 each may include a capping layer, a barrier layer, work function metal layers, and a fill material, as discussed above. As discussed above, the gate electrode layers 114 each has the gate electrode layer 114P for the p-type transistor (e.g. the p-type transistors P1 to P4) of the CFET and the gate electrode layer 114N for the n-type transistor (e.g. the n-type transistors N1 to N4) of the CFET.

The dielectric structures 230 are formed to replace the gate structures extending along and overlapping the cell boundaries CB and CB′ Therefore, as shown in FIGS. 11A and 11B, the dielectric structures 230 are formed on opposite sides of the gate structures 228-1 to 228-4 in the X-direction. The dielectric structures 230 will be divided into the dielectric structures 116 and 116′ discussed above.

Therefore, the circuit cell 102 with the CFETs C1 to C4 and the circuit cell 102′ with the CFETs C1′ to C4′ discussed above are provided, as shown in FIGS. 11A and 11B. In this fabrication stage shown in FIGS. 11A and 11B, the gate structures 228 are shared by the circuit cell 102 and 102′. The following fabrication stages will divide the gate structures 228 into the gate structures 106 and 106′ discussed above and show the formation of the conductive walls 128, 128′, 134, and 134′ discussed above.

Referring to FIGS. 12A to 12E, a mask layer 236 is formed over the gate structures 228 and the ILD layer 126, and a mask layer 238 is formed over the mask layer 236. The mask layers 236 and 238 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), or combinations thereof. After the formation of the mask layers 236 and 238, the mask layers 236 and 238 are patterned by performing lithography and etching processes to from openings 232, 234, and 234′ exposing portions of the gate structures 228 and the ILD layer 126.

Still referring to FIGS. 12A to 12E, the gate structures 228 and the ILD layer 126 not covered by the mask layers 236 and 238 are recessed. Specifically, the portions of the gate structures 228 and the ILD layer 126 are recessed through the openings 232, 234, and 234′ by recessing processes (e.g., etching processes). As such, the openings 232, 234, and 234′ are enlarged to extend into the gate structures 228 and the ILD layer 126. Furthermore, portions of the CESLs 124 over the isolation structures 210 are recessed. The openings 232, 234, and 234′ expose the top surfaces of the isolation structures 210.

As shown in FIGS. 12A to 12E, the gate structures 228 are divided into the gate structures 106 and 106′ discussed above and the dielectric structures 230 are divided into the dielectric structures 116 and 116′ discussed above by the openings 232, 234, and 234′. Furthermore, the gate spacers 214 are also divided in to the gate spacers 118 and 118′ discussed above. As shown in FIG. 12A, the opening 232 has a rolling pin shape in a top view. In some embodiments, as shown in FIGS. 12A to 12E, the opening 232 is formed between the circuit cells 102 and 102′ (more specifically, the CFETs C1 to C4 and the CFETs C1′ to C4′) in the Y-direction. In some embodiments, as shown in FIGS. 12A to 12E, the openings 234 and 234′ are respectively formed adjacent to the circuit cells 102 and 102′ (more specifically, the CFETs C1 to C4 and the CFETs C1′ to C4′) in the Y-direction. In some aspects, the opening 232 is formed between the gate structures 106 and 106′ in the Y-direction and between the source/drain features 122N/122P and 122N′/122′ in the Y-direction. In some aspects, the openings 234 and 234′ are respectively formed adjacent to the gate structures 106 and 106′ in the Y-direction and adjacent to the source/drain features 122N/122P and 122N′/122′ in the Y-direction. Furthermore, the opening 232 extends lengthwise and lengthwise overlaps the cell boundaries CB and CB′ (more specifically, the cell boundary line CBL), as shown in FIG. 12A. In some embodiments, the openings 234 and 234′ respectively extend lengthwise and respectively lengthwise overlap the cell boundaries CB and CB′, as shown in FIG. 12A.

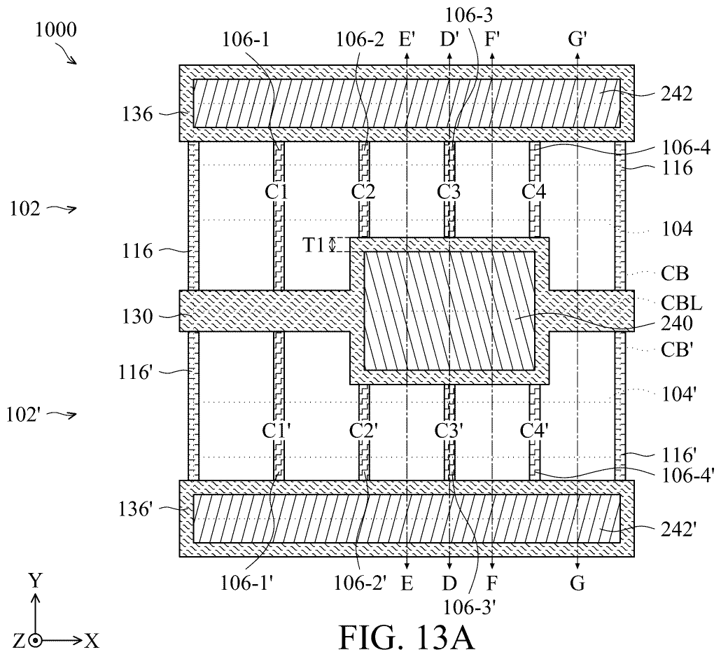

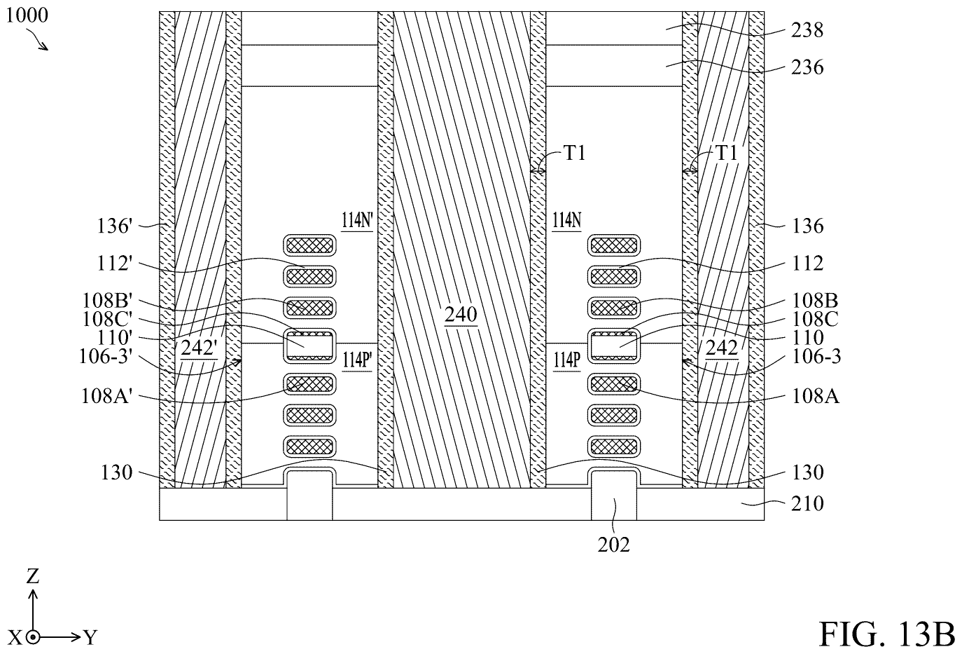

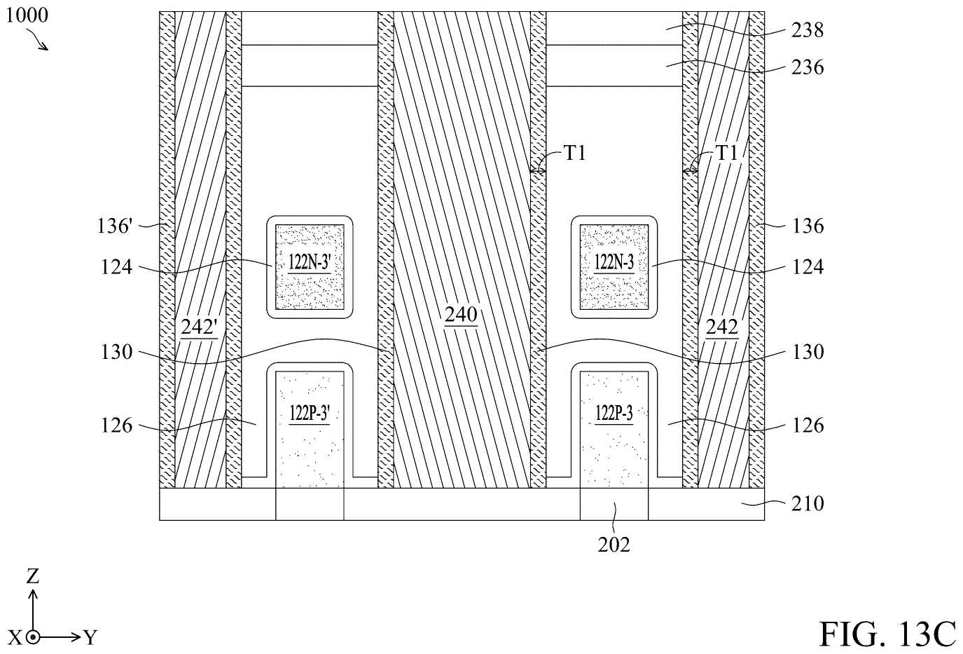

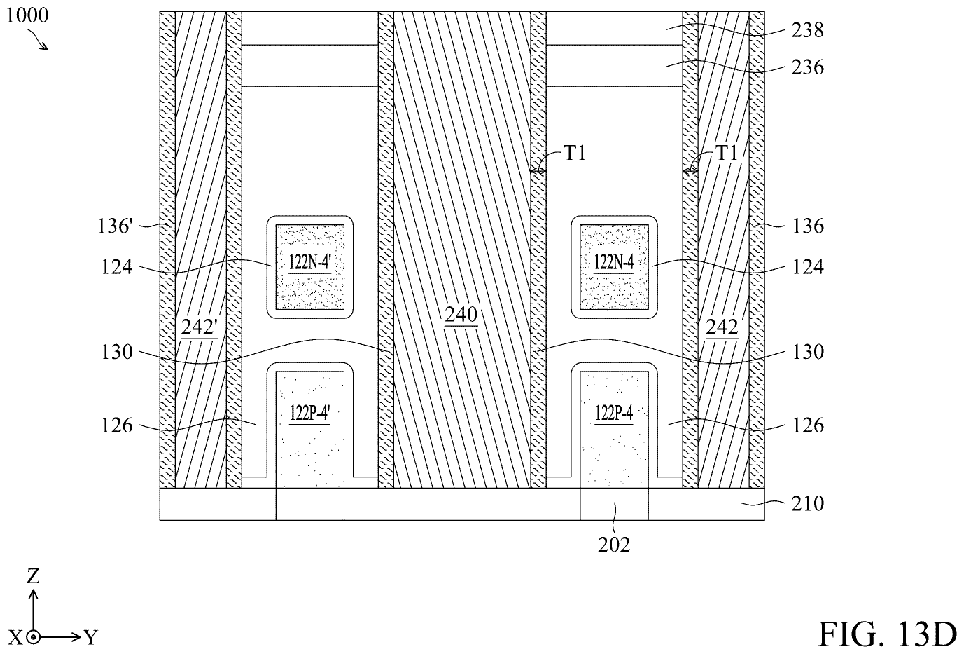

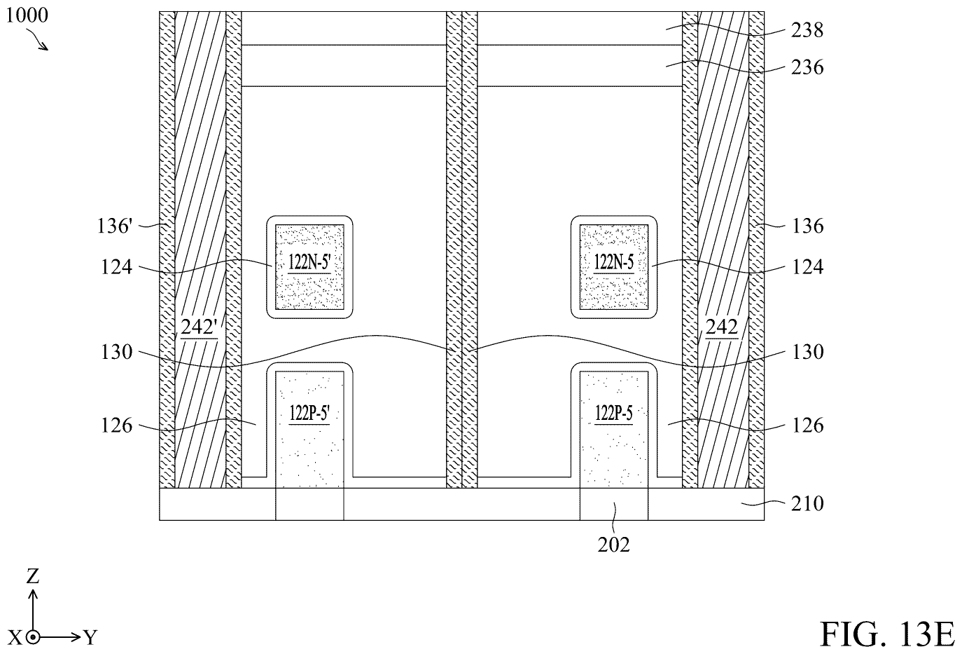

Referring to FIGS. 13A to 13E, the dielectric layers 130, 136, and 136′ discussed above are formed in the openings 232, 234, and 234′. More specifically, the dielectric layers 130, 136, and 136′ are conformally formed on sidewalls of the openings 232, 234, and 234′ to partially filling the openings 232, 234, and 234′. In some embodiments, the dielectric layers 130, 136, and 136′ are formed on sidewalls of the gate structures 106 and 106′ and the ILD layer 126. In some embodiments, a thickness of the dielectric layers 130, 136, and 136′ in the Y-direction is in a range from about 7 nm to about 9 nm. As shown in FIG. 13A, the dielectric layer 130 has a rolling pin shape in the top view. The dielectric layer 130 also overlaps the cell boundary CB and the cell boundary CB′ (more specifically, the cell boundary line CBL), as shown in FIGS. 1A and 1B. The dielectric layers 130, 136, and 136′ may include silicon nitride (Si₃N₄), silicon oxide (SiO₂), silicon carbide (SIC), silicon oxycarbide (SiOC), silicon oxynitride (SiON), silicon carbon nitride (SiCN), silicon oxycarbon nitride (SiOCN), or combinations thereof.

Still referring to FIGS. 13A to 13E, conductive structures 240, 242, and 242′ are formed in the openings 232, 234, and 234′. More specifically, a conductive material is formed to fill the remaining spaces of the openings 232, 234, and 234′ to form the conductive structures 240, 242, and 242′, as shown in FIGS. 13A to 13E. In some embodiments, the conductive structures 240, 242, and 242′ are formed within and in contact with the dielectric layers 130, 136, and 136′. In some embodiments, the conductive structures 240, 242, and 242′ are spaced apart from the gate structures 106 and 106′ by the dielectric layers 130, 136, and 136′ in the Y-direction, as shown in FIGS. 13A to 13E. As shown in FIG. 13A, the conductive structures 240, 242, and 242′ extend in the X-direction. Furthermore, the conductive structure 240 lengthwise overlaps the cell boundaries CB and CB′ (more specifically, the cell boundary line CBL), the conductive structure 242 lengthwise overlaps the cell boundary CB, and the conductive structure 242′ lengthwise overlaps the cell boundary CB′.

As shown in FIGS. 13A to 13E, the conductive structure 240 is formed between the circuit cells 102 and 102′ (more specifically, between the CFETs C2 to C4 and the CFETs C2′ to C4′) in the Y-direction. In some embodiments, as shown in FIGS. 13A to 13E, the conductive structures 242 and 242′ are respectively formed adjacent to the circuit cells 102 and 102′ (more specifically, the CFETs C1 to C4 and the CFETs C1′ to C4′) in the Y-direction. In some aspects, the conductive structure 240 is formed between the gate structures 106-2 to 106-4 and 106′-2 to 106-4′ in the Y-direction. In some aspects, the conductive structures 242 and 242′ are respectively formed adjacent to the gate structures 106 and 106′ in the Y-direction. In some aspects, as shown in FIG. 13A, the CFETs C2 to C4 (specifically, the gate structures 106-2 to 106-4) are between the conductive structures 240 and 242 in the Y-direction, and the CFETs C2′ to C4′ (specifically, the gate structures 106-2′ to 106-4′) are between the conductive structures 240 and 242′ in the Y-direction.

The conductive material of the conductive structures 240, 242, and 242′ is selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

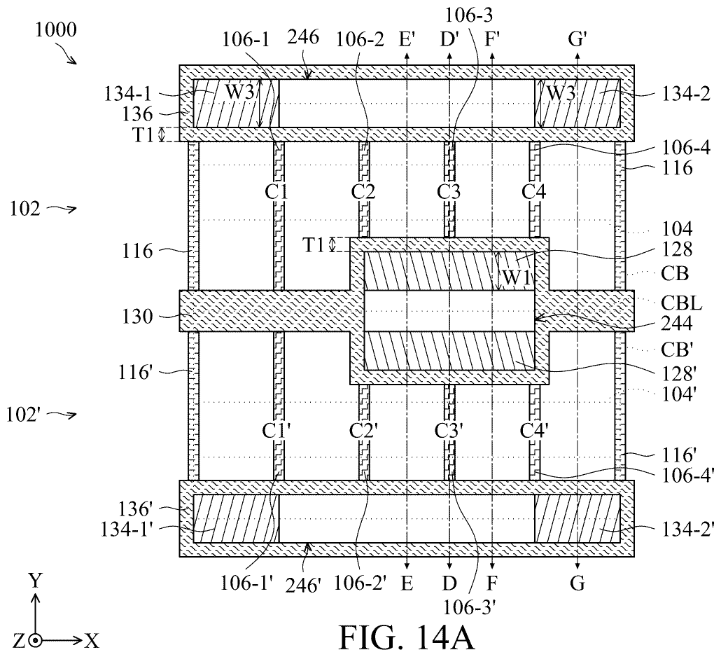

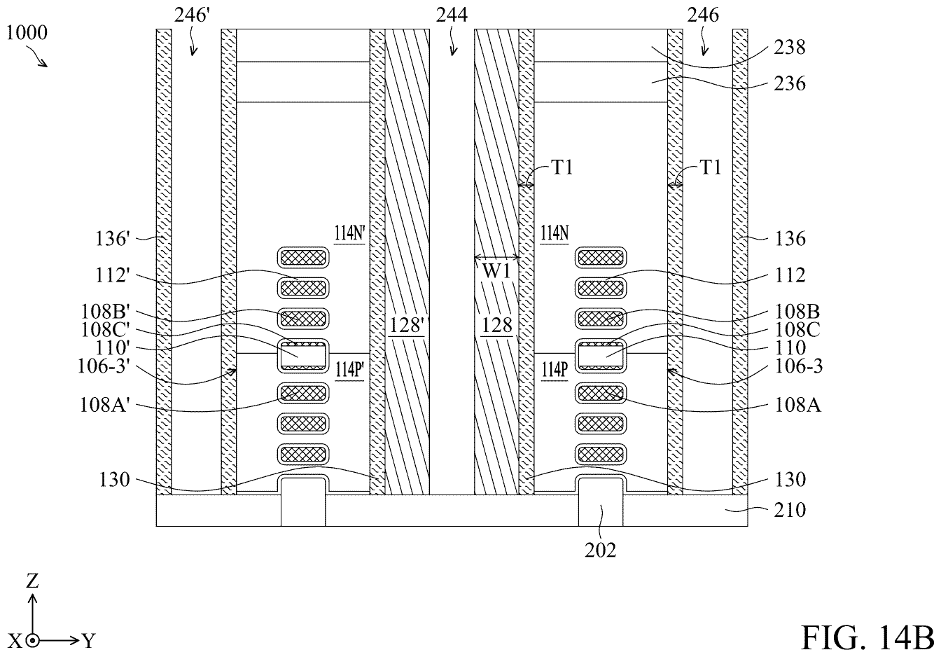

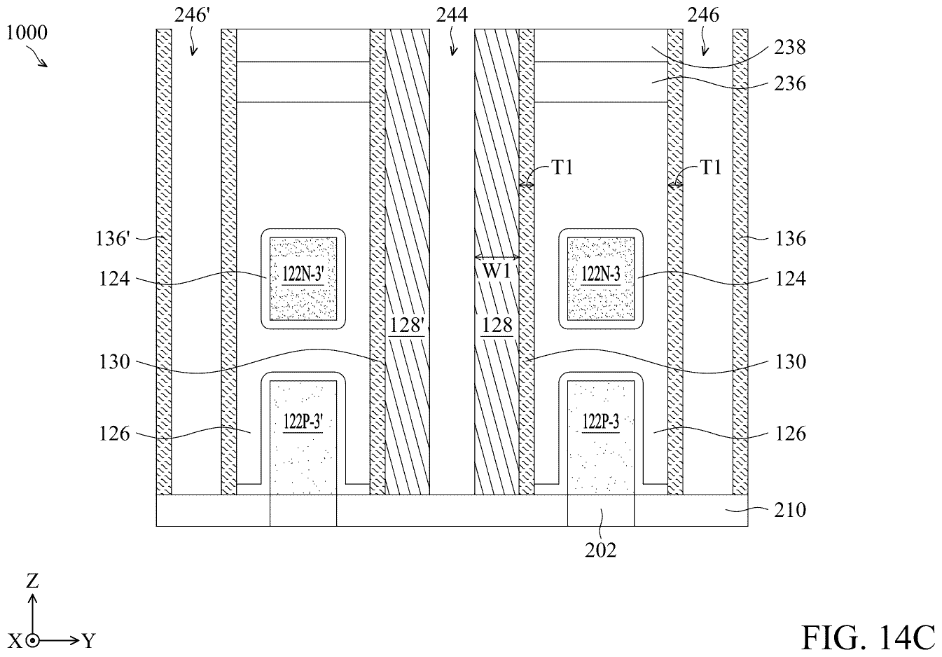

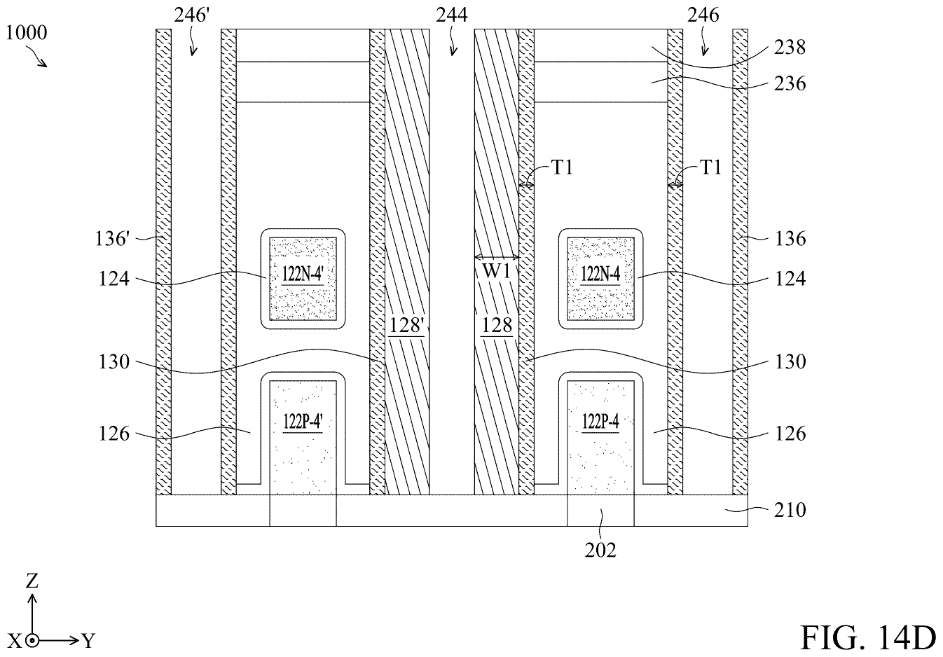

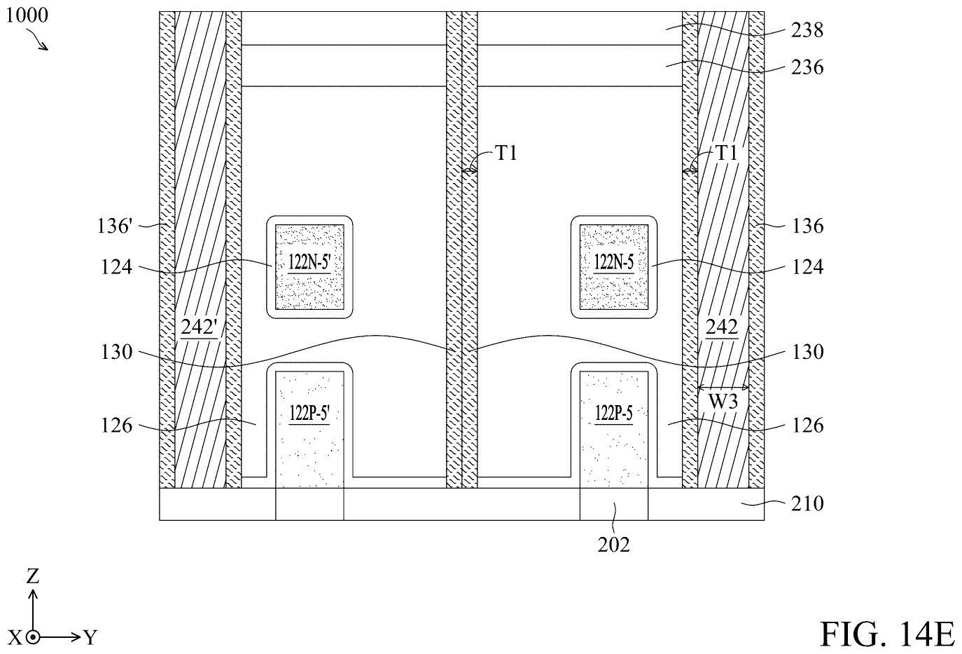

Referring to FIGS. 14A to 14E, portions of the conductive structures 240, 242, and 242′ are removed. More specifically, lithography and etching processes may be performed to remove the portions of the conductive structures 240, 242, and 242′ to form openings 244, 246, and 246′, as shown in FIGS. 14A to 14E. The etching processes are selective that selectively etches the portions of the conductive structures 240, 242, and 242′, with minimal (or no) etching of the dielectric layers 130, 136, and 136′. As shown in FIGS. 14A to 14E, the removal of the portions of the conductive structures 240, 242, and 242′ divide or cut the conductive structure 240 into the conductive walls 128 and 128′ discussed above, the conductive structure 242 into the conductive walls 134-1 and 134-2 discussed above, and the conductive structure 242′ into the conductive walls 134-1′ and 134-2′ discussed above. Therefore, the conductive walls 128 and 128′ are separated from each other in the Y-direction, the conductive walls 134-1 and 134-2 are separated from each other in the X-direction, and the conductive walls 134-1′ and 134-2′ are separated from each other in the X-direction.

The conductive walls 128, 128′, 134-1, 134-2, 134-1′, and 134-2′ are formed from the conductive structures 240, 242, and 242′, such that conductive walls 128, 128′, 134-1, 134-2, 134-1′, and 134-2′ include the conductive material of the conductive structures 240, 242, and 242′ discussed above. In some embodiments, the conductive walls 128, 128′, 134-1, 134-2, 134-1′, and 134-2′ include metal material and may be referred to as metal walls.

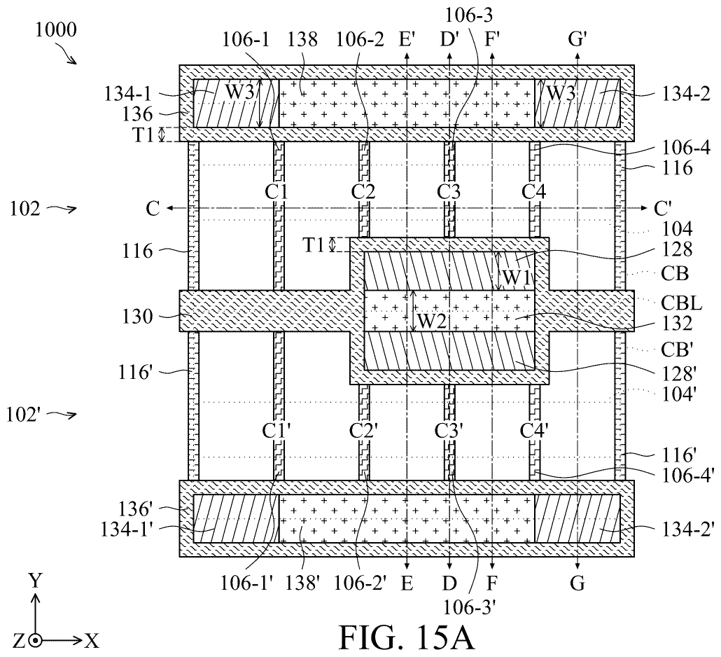

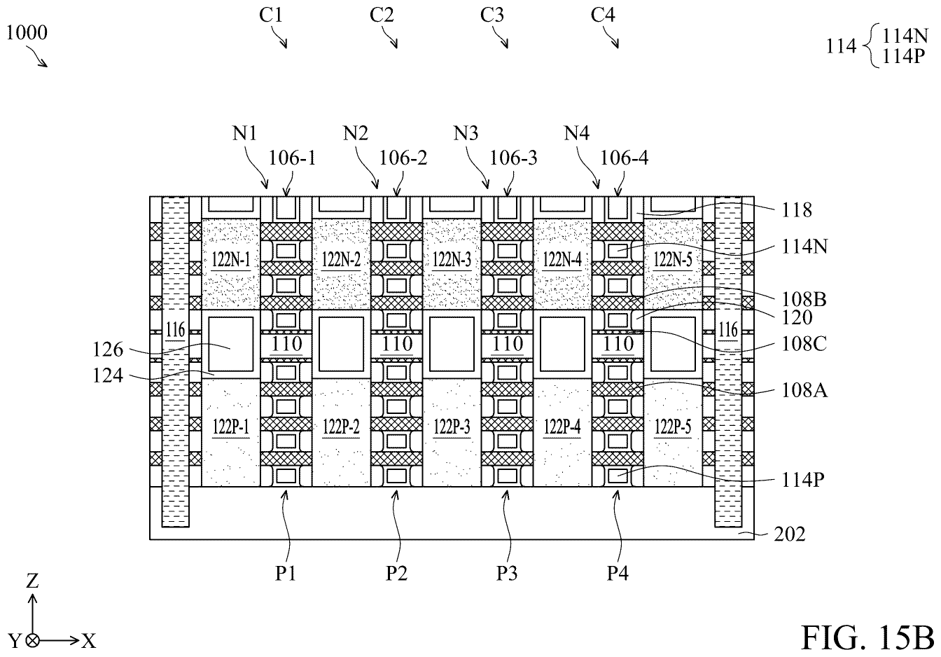

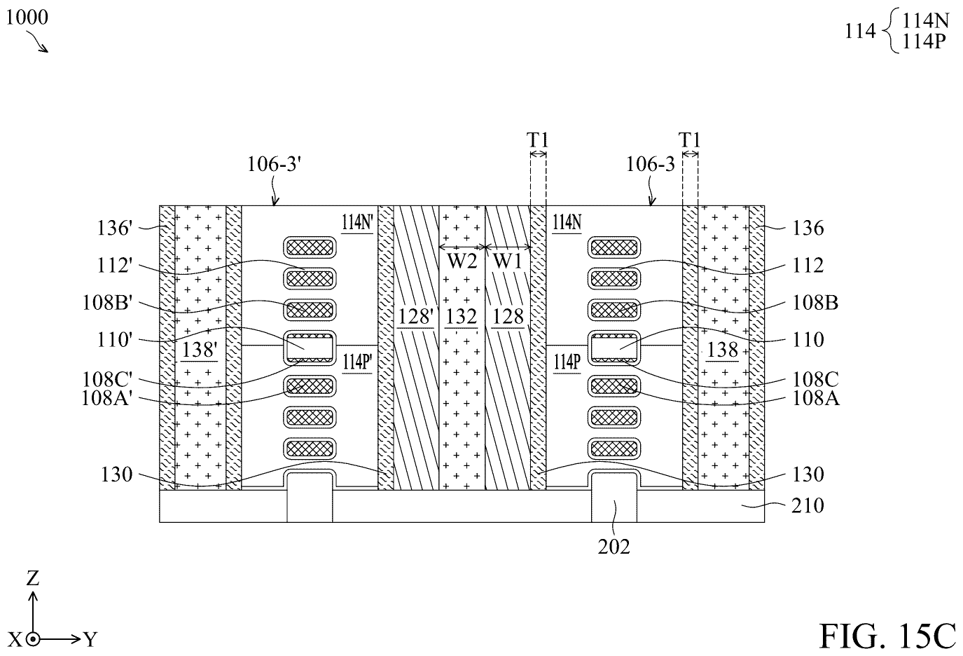

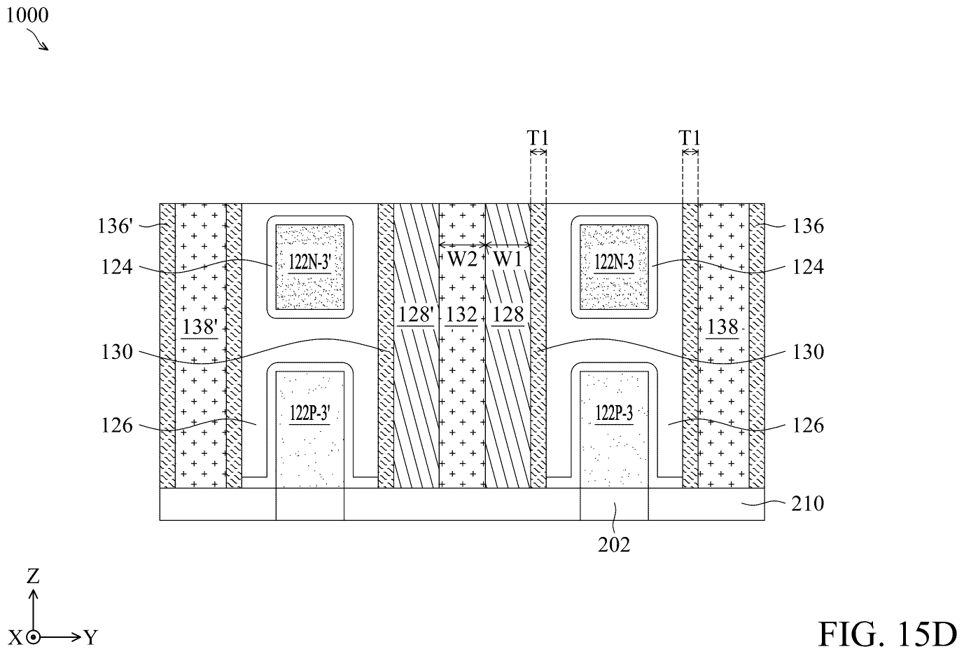

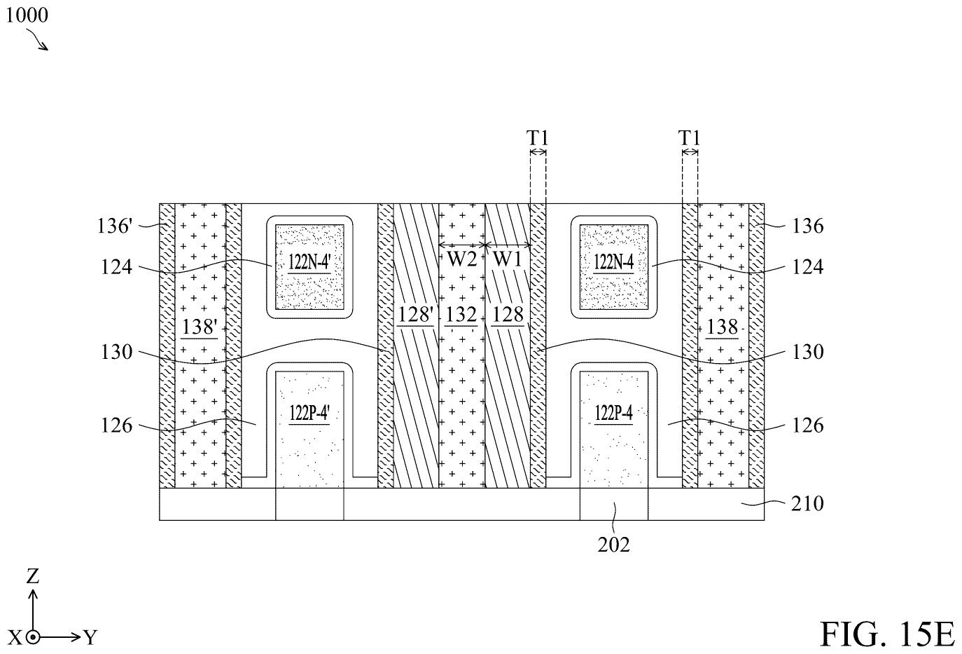

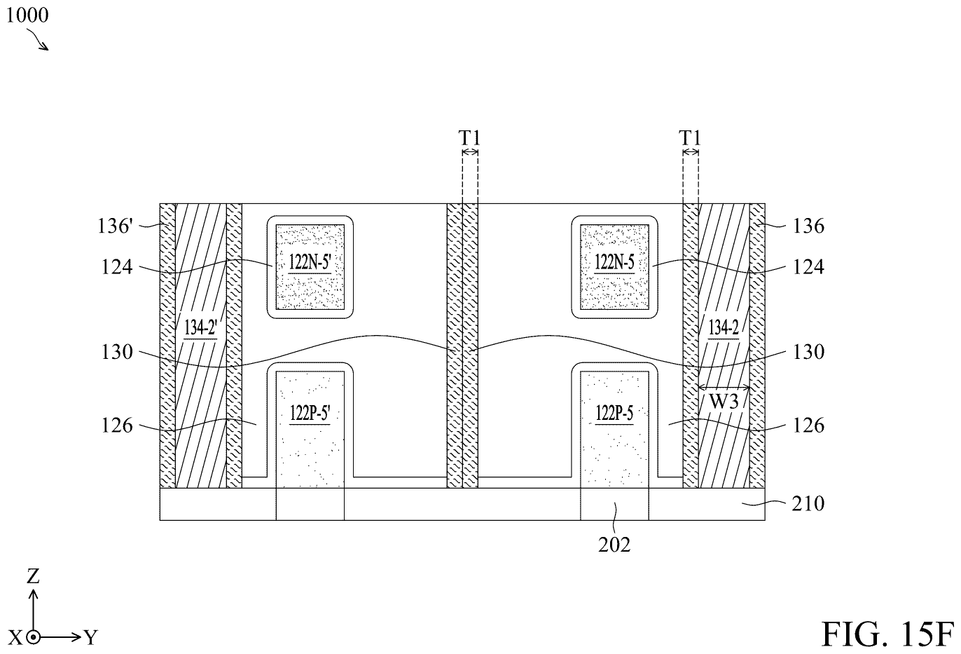

Referring to FIGS. 15A to 15F, the dielectric structures 132, 138, and 138′ discussed above are formed in the openings 244, 246, and 246′. More specifically, a dielectric material is formed to fill the openings 244, 246, and 246′ to form the dielectric structures 132, 138, and 138′, as shown in FIGS. 13A to 13E. The dielectric structure 132 is also formed between and in contact with the conductive walls 128 and 128′ in the Y-direction, the dielectric structure 138 is also formed between and in contact with the conductive walls 134-1 and 134-2 in the X-direction, and the dielectric structure 138′ is also formed between and in contact with the conductive walls 134-1′ and 134-2′ in the X-direction, as shown in FIGS. 15A to 15E.

In some embodiments, the dielectric structures 132, 138, and 138′ are also formed within and in contact with the dielectric layers 130, 136, and 136′ Furthermore, the dielectric layer 130 is in contact with the dielectric structure 132 in the X-direction, the dielectric layer 136 is in contact with the dielectric structure 138 in the Y-direction, and the dielectric layer 136′ is in contact with the dielectric structure 138′ in the Y-direction. As shown in FIG. 15A, the dielectric structures 132, 138, and 138′ extend in the X-direction. Furthermore, the dielectric structure 132 lengthwise overlaps the cell boundaries CB and CB′ (more specifically, the cell boundary line CBL), the dielectric structure 138 lengthwise overlaps the cell boundary CB, and the dielectric structure 138′ lengthwise overlaps the cell boundary CB′.

The dielectric material of the dielectric structures 132, 138, and 138′ include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), or combinations thereof. As shown in FIGS. 15A to 15F, a width of the dielectric structures 138 and 138′ in the Y-direction are in a range from about 18 nm to about 22 nm. In some embodiments, a width W3 of the conductive walls 134-1, 134-2, 134-1′, and 134-2′ in the Y-direction are also in a range from about 18 nm to about 22 nm. As shown in FIGS. 15A to 15F, a width W2 of the dielectric structure 132 in the Y-direction is in a range from about 20 nm to about 24 nm. As such, a distance between the conductive walls 128 and 128′ is also in a range from about 20 nm to about 24 nm.

In some embodiments, a width W1 of the conductive walls 128 and 128′ in the Y-direction is in a range from about 11 nm to about 13 nm. The conductive walls 128, 128′, 134-1, 134-2, 134-1′, and 134-2′ are spaced apart from (or adjacent to) the gate structures 106 and 106′ in the Y-direction, as show in FIGS. 15A to 15F. As shown in FIGS. 15A to 15F, the dielectric layers 130, 136, and 136′ are between the gate structures 106 and 106′ and the conductive walls 128, 128′, 134-1, 134-2, 134-1′, and 134-2′ in the Y-direction. As discussed above, the thickness T1 of the dielectric layers 130, 136, and 136′ in the Y-direction is in a range from about 7 nm to about 9 nm. Therefore, a distance between the conductive walls 128, 128′, 134-1, 134-2, 134-1′, and 134-2′ and the gate structures 106 and 106′ in the Y-direction is also in a range from about 7 nm to about 9 nm.

Still referring to FIGS. 15A to 15F, a planarization process may be performed to remove the mask layers 236 and 238 and thin (decrease) the heights of the dielectric layers 130, 136, and 136′, the conductive walls 128, 128′, 134-1, 134-2, 134-1′, and 134-2′, the dielectric structures 132, 138, and 138′, the gate structures 106 and 106′, and the ILD layer 126. The planarization process may be e.g., a grinding or a CMP, and may be performed such that the top surfaces of the dielectric layers 130, 136, and 136′, the conductive walls 128, 128′, 134-1, 134-2, 134-1′, and 134-2′, the dielectric structures 132, 138, and 138′, the gate structures 106 and 106′, and the ILD layer 126 are level or are substantially level.

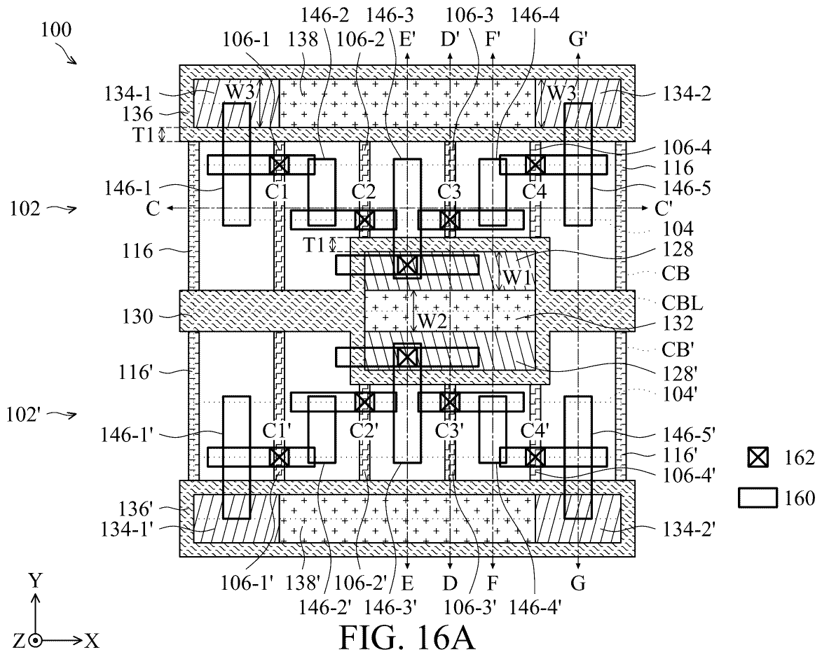

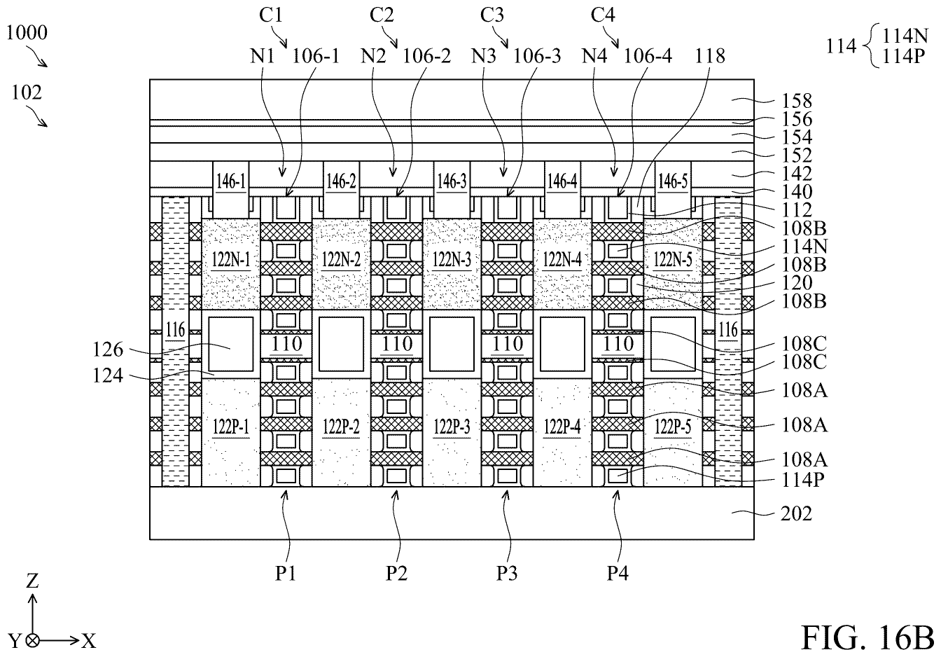

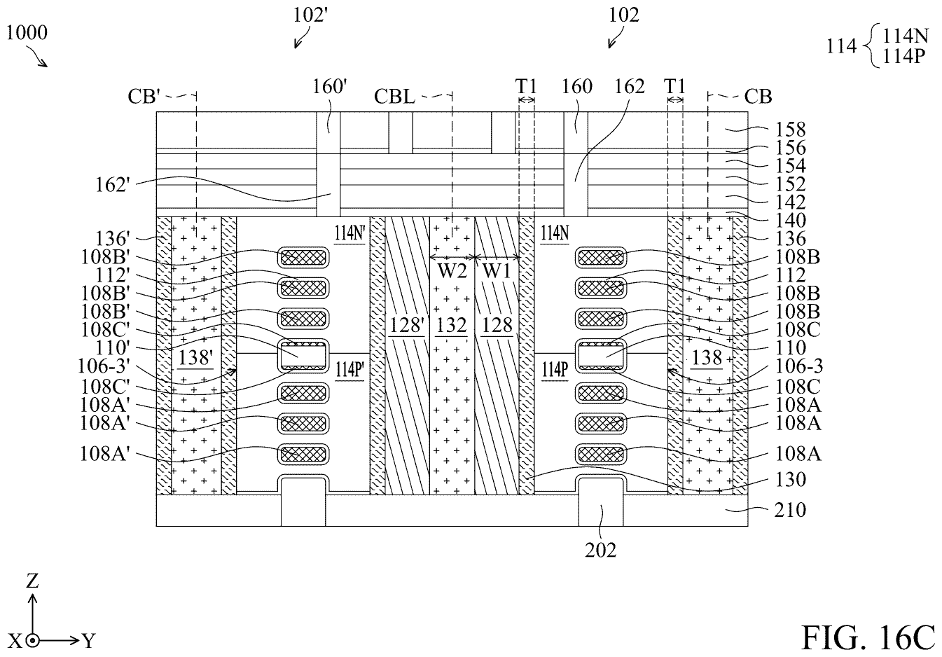

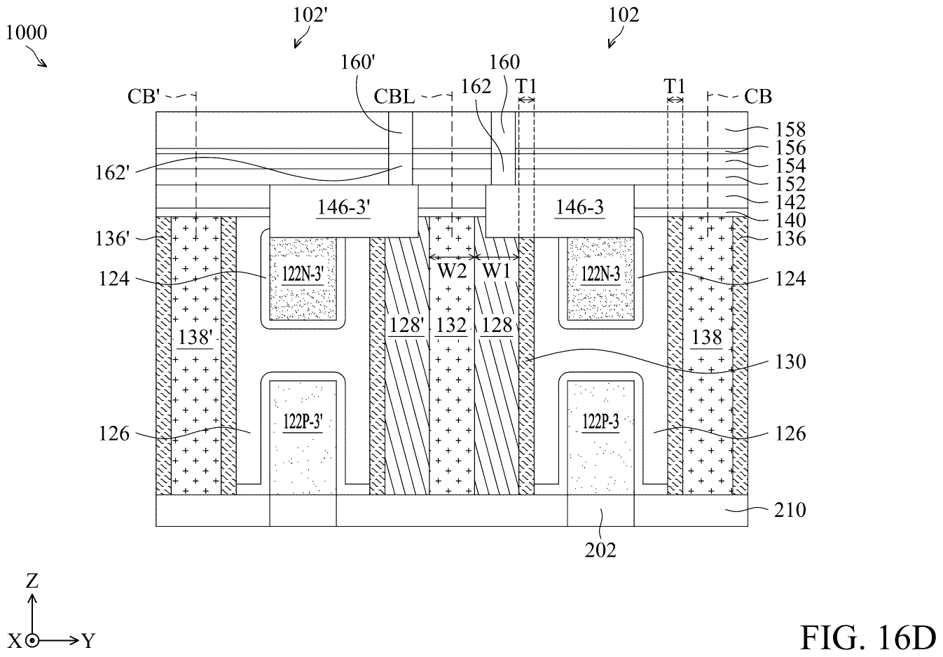

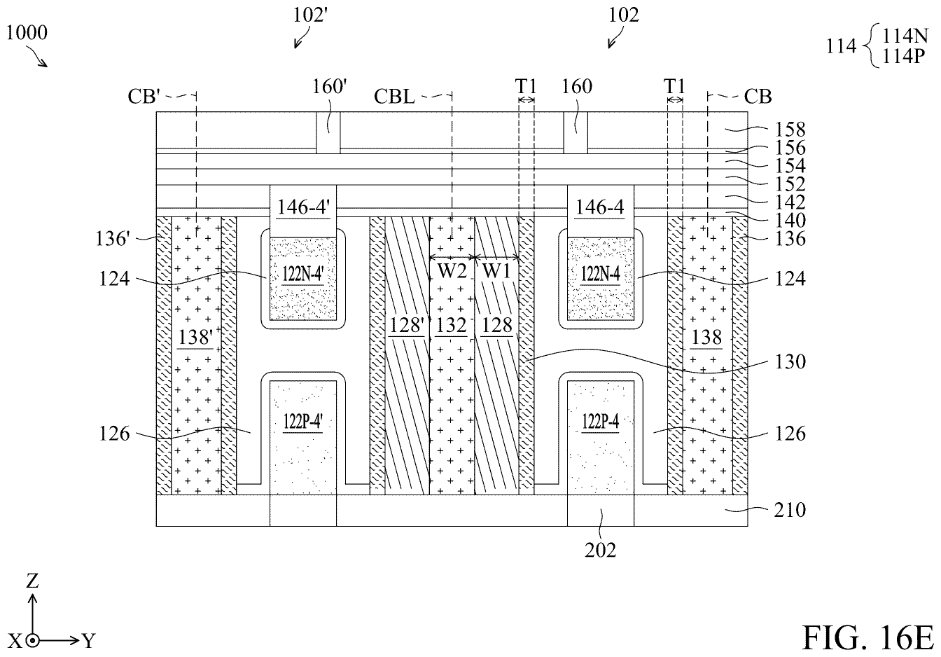

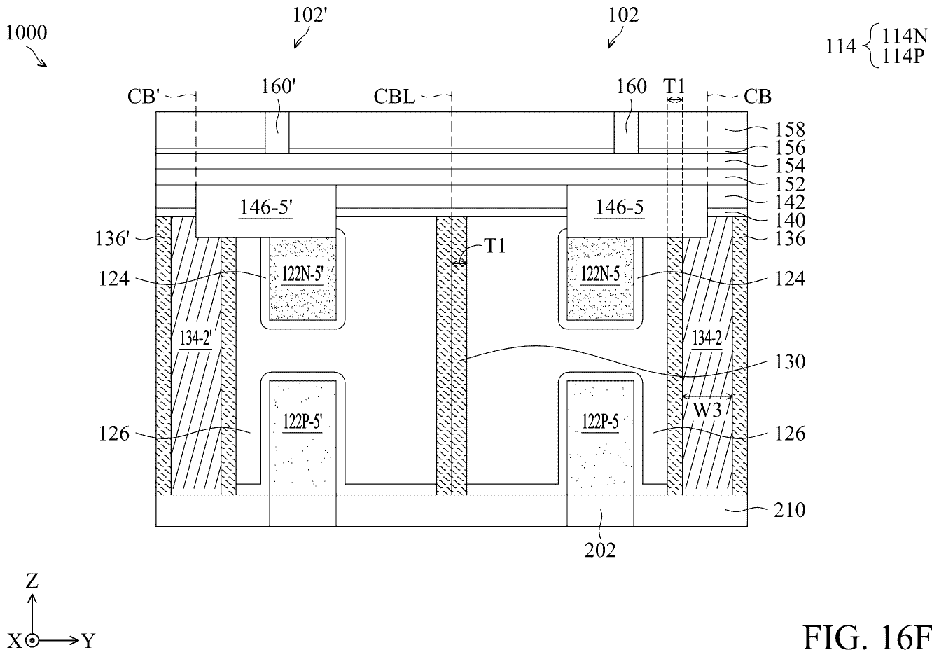

Referring to FIGS. 16A to 16F, the dielectric layers 140 and 142 discussed above are formed over the workpiece 1000. Specifically, the dielectric layer 140 is formed over and covers the dielectric layers 130, 136, and 136′, the conductive walls 128, 128′, 134-1, 134-2, 134-1′, and 134-2′, the dielectric structures 132, 138, and 138′, the gate structures 106 and 106′, and the ILD layer 126, and the dielectric layer 142 is formed over the dielectric layer 140.

Still referring to FIGS. 16A to 16F, the source/drain contacts 146-1 to 146-5 (furthermore, the source/drain contacts 146-1′ to 146-5′) discussed above are formed in the CESLs 124, the ILD layer 126, and the dielectric layers 140 and 142. As discussed above, the source/drain contacts 146-1 to 146-5 are also respectively formed over, in contact with, and electrically connected to the source/drain features 122N-1 to 122N-5. It should be understood that the source/drain contacts 146-1′ to 146-5′ are also respectively formed over, in contact with, and electrically connected to the source/drain features 122N-1′ to 122N-5′. It is noted that the source/drain contact 146-1 is also formed over, in contact with, and electrically connected to the conductive wall 134-1, such that the source/drain contact 146-1 electrically connects the source/drain feature 122N-1 to the conductive wall 134-1; the source/drain contact 146-3 is also formed over, in contact with, and electrically connected to the conductive wall 128, such that the source/drain contact 146-3 electrically connects the source/drain feature 122N-3 to the conductive wall 128; and the source/drain contact 146-5 is also formed over, in contact with, and electrically connected to the conductive wall 134-2, such that the source/drain contact 146-5 electrically connects the source/drain feature 122N-5 to the conductive wall 134-2, as shown in FIGS. 16A to 16F.

Still referring to FIGS. 16A to 16F, the front-side interconnection structure discussed above is formed over the workpiece 1000. The front-side interconnection structure includes the CESL 152, the ILD layer 154, the CESL 156, the ILD layer 158, the metal conductors 160 (furthermore, the metal conductors 160′), and the vias 162 (furthermore, the vias 162′). The CESL 152 is formed over the dielectric layer 142 and source/drain contacts 146. The ILD layer 154 is formed over CESL 152. The CESL 156 is formed over the ILD layer 154 and the ILD layer 158 is formed over the CESL 156. The metal conductors 160 and 160′ are formed over the ILD layer 154 and passing through the CESL 156 and the ILD layer 158. The vias 162/162′ are formed passing through the ILD layer 154, the CESL 152, the dielectric layer 142, and dielectric layer 140 to electrically connect the gate structures 106/106′ or the source/drain contacts 146/146′ to the metal conductors 160/160′, as shown in FIGS. 16A to 16F.

After the formation of the front-side interconnection structure, the workpiece 1000 may be flipped to form back-side source/drain contacts and a back-side interconnection structure. For the purpose of simplicity, the sequent figures are shown without being flipped. Referring back to FIGS. 1A to 1G, the substrate 202 and the isolation structures 210 are removed. More specifically, one or more selective etching processes are performed that selectively etches the substrate 202 and the isolation structures 210, with minimal (or no) etching of the gate structures 106 and 106′, the source/drain features 122P and 122P′, the CESLs 124, the dielectric layers 130, 136, and 136′, the dielectric structures 132, 138, and 138′, and the conductive walls 128, 128′, 134-1, 134-2, 134-1′, and 134-2′. The selective etching process is a dry etching process, a wet etching process, other suitable etching process, or combinations thereof.

Still referring back to FIGS. 1A to 1G, the dielectric layer 144 is formed. More specifically, the dielectric layer 144 is conformally formed under and on bottom surfaces of the gate structures 106 and 106′, the source/drain features 122P and 122P′, the CESLs 124, the dielectric layers 130, 136, and 136′, the dielectric structures 132, 138, and 138′, and the conductive walls 128, 128′, 134-1, 134-2, 134-1′, and 134-2′.

Still referring back to FIGS. 1A to 1G, the source/drain contacts 148-1 to 148-5 (furthermore, the source/drain contacts 148-1′ to 148-5′) and the contact features 150-1 and 150-2 (furthermore, the contact features 150-1′ and 150-2′) discussed above are formed in the dielectric layer 144. As discussed above, the source/drain contacts 148-1 to 148-5 are also respectively formed under, in contact with, and electrically connected to the source/drain features 122P-1 to 122P-5. In some embodiments, the contact features 150-1 and 150-2 are also respectively formed under, in contact with, and electrically connected to the conductive walls 134-1 and 134-2. It should be understood that the source/drain contacts 148-1′ to 148-5′ are also respectively formed under, in contact with, and electrically connected to the source/drain features 122P-1′ to 122P-5′, and the contact features 150-1′ and 150-2′ are also respectively formed under, in contact with, and electrically connected to the conductive walls 134-1′ and 134-2′. It is noted that the source/drain contact 148-4 is also formed under, in contact with, and electrically connected to the conductive wall 128, such that the source/drain contact 148-4 electrically connects the source/drain feature 122P-4 to the conductive wall 128.

Still referring to FIGS. 1A to 1G, the back-side interconnection structure discussed above is formed under the workpiece 1000. The back-side interconnection structure includes the CESL 166, the ILD layer 168, the CESL 170, the ILD layer 172, the metal conductors 174-1 to 174-3 (furthermore, the metal conductors 174-1′ and 174-2′), and the vias 176-1 to 176-6 (furthermore, the vias 176-1′ to 176-6′). The CESL 166 is formed under the dielectric layer 144, source/drain contacts 148, and the contact features 150. The ILD layer 168 is formed under the CESL 166. The CESL 170 is formed under the ILD layer 168 and the ILD layer 172 is formed under the CESL 170.

The metal conductors 174-1, 174-2, 174-3, 174-1′, and 174-2′ are formed under ILD layer 168 and pass through CESL 170 and the ILD layer 172. The vias 176-1 to 176-6 and 176-1′ to 176-6′ are formed pass through the CESL 166 and the ILD layer 168 to electrically connect the source/drain contacts 148/148′ or the contact features 150/150′ to the metal conductors 174/174′, as shown in FIGS. 1C to 1G.

In some embodiments, the metal conductor 174-1 and 174-1′ are formed under and overlapping the conductive wall 134-1 and 134-2 and the conductive wall 134-1′ and 134-2′, as shown in FIGS. 1A to 1G. The metal conductor 174-1 and 174-1′ are electrically connected to a voltage source VSS to serve as the VSS lines to supply power for the circuit cell 102 and 102′, respectively. For example, as shown in FIGS. 1A to 1G, the metal conductor 174-1 serving as the VSS line is electrically connected to the source/drain features 122N-1 and 122N-5 through the vias 176-1 and 176-2, the contact features 150-1 and 150-2, the conductive wall 134-1 and 134-2, and the source/drain contacts 146-1 and 146-5.

In some embodiments, the metal conductor 174-3 are formed under and overlapping the conductive wall 128 and 128′, as shown in FIGS. 1A to 1G. The metal conductor 174-3 is electrically connected to a voltage source VDD to serve as the VDD line to supply power for the circuit cells 102 and 102′. For example, as shown in FIGS. 1A to 1G, the metal conductor 174-3 serving as the VDD line is electrically connected to the source/drain features 122P-2 through the via 176-4 and the source/drain contact 150-2.

As discussed above, the conductive walls 128 and 128′ are respectively used for the local connections of the circuit cells 102 and 102′. For example, as shown in FIGS. 1A to 1G, the source/drain feature 122N-3 is electrically connected to the source/drain features 122P-4 through the source/drain contact 146-3, the conductive wall 128, and the source/drain contact 150-4. It is noted that the conductive walls 128 and 128′ are formed by cutting the conductive structure 240, as discussed above. If the conductive walls 128 and 128′ are formed directly and independently, there is a risk of the short of the conductive walls 128 and 128′. Therefore, the formation of the conductive walls 128 and 128′ by cutting the conductive structure 240 has a larger process window and good process reliability.

The conductive walls 134 (including the conductive walls 134-1 and 134-2) and the conductive walls 134′ (including the conductive walls 134-1′ and 134-2′) are electrically connected to the metal conductor 174-1 and 174-1′ serving as the VSS lines. Therefore, the conductive walls 134 and 134′ are also referred to as power walls. In convention, the power wall is a continuous extension structure. However, the conductive walls 134 (including the conductive walls 134-1 and 134-2) and the conductive walls 134′ (including the conductive walls 134-1′ and 134-2′) are respectively formed by cutting the conductive structures 242 and 242′ to serve as the power walls rather than in direct using the conductive structures 242 and 242′, as discussed above. This is because the gate structures 106 and 106′ and the source/drain features 122N, 122P, 122N′, and 122P′ of the CFETs C2, C3, C2′, and C3′ in the circuit cells 102 and 102′ do not need to be electrically connected to the metal conductor 174-1 and 174-1′. Therefore, portions of the conductive structures 242 and 242′ adjacent to the gate structures 106 and 106′ and the source/drain features 122N, 122P, 122N′, and 122P′ of the CFETs C2, C3, C2′, and C3′ in the Y-direction are removed, such that the parasitic capacitance are reduced.

Furthermore, as shown in FIGS. 1A to 1G, the width W1 of the conductive walls 128 and 128′ in the Y-direction is in a range from about 11 nm to about 13 nm, and the width W3 of the conductive walls 134-1, 134-2, 134-1′, and 134-2′ in the Y-direction are in a range from about 18 nm to about 22 nm, as discussed above. If the widths W1 and W3 of the conductive walls 128, 128′, 134-1, 134-2, 134-1′, and 134-2′ are too small (the width W1 is less than about 11 nm and the width W3 is less than about 18 nm), the resistance of the conductive walls 128, 128′, 134-1, 134-2, 134-1′, and 134-2′ are increased. If the widths W1 and W3 of the conductive walls 128, 128′, 134-1, 134-2, 134-1′, and 134-2′ are too large (the width W1 is greater than about 13 nm and the width W3 is greater than about 22 nm), the footprint of the conductive walls 128, 128′, 134-1, 134-2, 134-1′, and 134-2′ in the circuit cells 102 and 102′ are increased, thereby reducing the performance of the circuit cells 102 and 102′.

As shown in FIGS. 1A to 1G, the width W2 of the dielectric structure 132 in the Y-direction is in a range from about 20 nm to about 24 nm, as discussed above. If the width W2 of the dielectric structure 132 is too small (the width W2 is less than about 20 nm), the distance between the conductive walls 128 and 128′ in the Y-direction is too close, thereby increasing the parasitic capacitance between the conductive walls 128 and 128′. If the width W2 of the dielectric structure 132 is too large (the width W2 is greater than about 24 nm), the footprint of the dielectric structure 132 are increased or the width W1 of the conductive walls 128 and 128′ are reduced, thereby reducing the performance of the circuit cells 102 and 102′.

As shown in FIGS. 1A to 1G, the thickness T1 of the dielectric layers 130, 136, and 136′ in the Y-direction is in a range from about 7 nm to about 9 nm, as discussed above. This also represents that the distance between the conductive walls 128, 128′, 134-1, 134-2, 134-1′, and 134-2′ and the gate structures 106 and 106′ in the Y-direction is in a range from about 7 nm to about 9 nm. If the thickness T1 of the dielectric layers 130, 136, and 136′ in the Y-direction is too small (the thickness T1 is less than about 7 nm), the distance between the conductive walls 128, 128′, 134-1, 134-2, 134-1′, and 134-2′ and the gate structures 106 and 106′ in the Y-direction is too close, thereby increasing the parasitic capacitance between the conductive walls 128, 128′, 134-1, 134-2, 134-1′, and 134-2′ and the gate structures 106 and 106′. If the width W2 of the dielectric structure 132 is too large (the thickness T1 is greater than about 9 nm), the footprint of the dielectric layers 130, 136, and 136′ are increased, thereby reducing the performance of the circuit cells 102 and 102′.

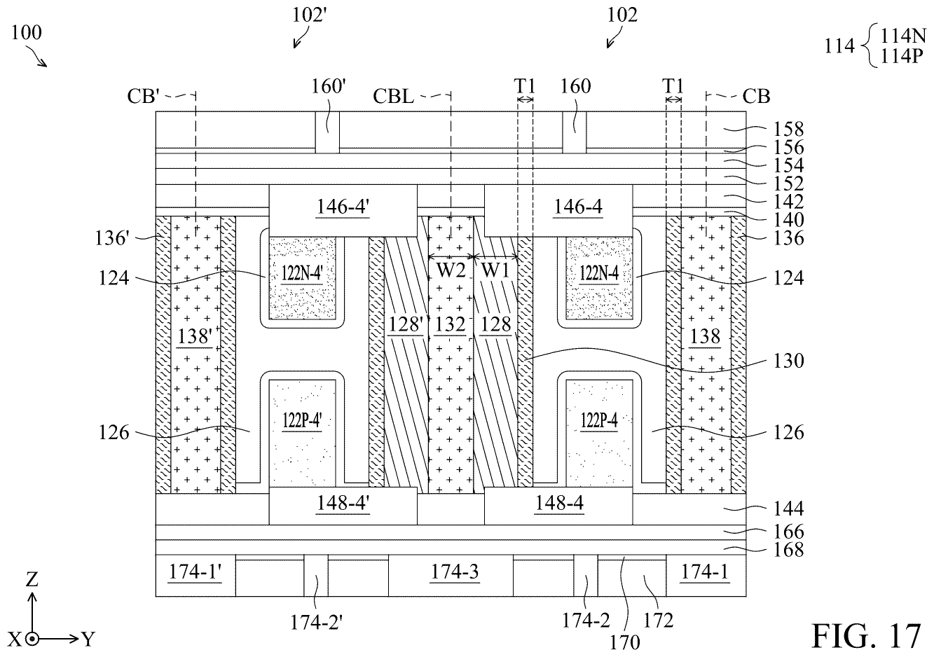

FIG. 17 is a Y-Z cross-sectional view of the semiconductor structure 100 along a line F-F′ in FIGS. 1A and 1B, in accordance with some alternative embodiments of the present disclosure. Referring back to FIGS. 1A to 1G, as discussed above, the conductive wall 128 used for the local connection is electrically connected to the source/drain feature 122N-3 and the source/drain feature 122P-4, as discussed above. In such embodiment, the source/drain feature 122N-3 and the source/drain feature 122P-4 are on opposite sides of the gate structure 106-3 of the CFET C3. The source/drain feature 122N-3 is higher than the source/drain feature 122P-4, as shown in FIGS. 1C, 1E, and 1F. The conductive wall for local connection may also be used for connecting the source/drain features on the same side of the CFET. As shown in FIG. 17, the source/drain contact 146-4 extend to be over and in contact with the source/drain feature 122N-4, such that the source/drain feature 122N-4 in direct over the source/drain feature 122P-4 is electrically connected to the source/drain feature 122P-4 through the source/drain contact 146-4, the conductive wall 128, and the source/drain contact 148-4.

The embodiments disclosed herein relate to semiconductor structures and their manufacturing methods, and more particularly to methods and semiconductor structures including CFETs with interconnection walls formed by cutting process to enhance process window and improve CFET design. Furthermore, the present embodiments provide one or more of the following advantages.

Thus, one of the embodiments of the present disclosure describes a method for manufacturing a semiconductor structure that includes providing a first circuit cell and a second circuit cell arranged in a first direction. Each of the first circuit cell and the second circuit cell includes complementary field-effect transistors (CFETs) arranged in a second direction perpendicular to the first direction. Each of the CFETs includes a first transistor and a second transistor over the first transistor. The method further includes forming a first conductive structure between the first circuit cell and the second circuit cell in the first direction, and removing a portion of the first conductive structure to divide the first conductive structure into a first conductive wall and a second conductive wall separated from each other in the first direction. The first conductive wall is used for a local connection of the first circuit cell and the second conductive wall is used for a local connection of the second circuit cell.

In another of the embodiments, discussed is a method for manufacturing a semiconductor structure including forming a fin over a substrate. The fin includes first semiconductor layers and second semiconductor layers alternately stacked. The method further includes forming dummy gate structures over the fin, forming p-type source/drain features on opposite sides of the dummy gate structures in a first direction, forming n-type source/drain features over the p-type source/drain features, replacing the dummy gate structures and the first semiconductor layers with gate structures wrapping around the second semiconductor layers, forming a first conductive structure spaced apart from the gate structures in a second direction perpendicular to the first direction, and removing a portion of the first conductive structure to divide the first conductive structure into a first conductive wall and a second conductive wall separated from each other in the second direction. The first conductive wall is electrically connected to one of the p-type source/drain features and one of the n-type source/drain features.

In yet another of the embodiments, discussed is a semiconductor structure including a first circuit cell, a second circuit cell, a first conductive wall and a second conductive wall, a dielectric structure, a dielectric layer, a first source/drain contact, and a second source/drain contact. The first circuit cell includes first complementary field-effect transistors (CFETs) arranged in a first direction. The second circuit cell arranged with the first circuit cell in a second direction perpendicular to the first direction. The second circuit cell includes second CFETs arranged in the first direction. The first conductive wall and the second conductive wall are between the first CFETs and the second CFETs in the second direction. The dielectric structure is between and in contact with the first conductive wall and the second conductive wall in the second direction. The dielectric layer wraps around the first conductive wall, the second conductive wall, and the dielectric structure in a top view. The first source/drain contact is over and in contact with the first conductive wall and a first source/drain feature of the first CFETs. The second source/drain contact is under and in contact with the first conductive wall and a second source/drain feature of the first CFETs. The first source/drain feature is higher than the second source/drain feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
providing a first circuit cell and a second circuit cell arranged in a first direction, wherein each of the first circuit cell and the second circuit cell comprises:
complementary field-effect transistors (CFETs) arranged in a second direction perpendicular to the first direction, wherein each of the CFETs comprises a first transistor and a second transistor over the first transistor;
forming a first conductive structure between the first circuit cell and the second circuit cell in the first direction; and
removing a portion of the first conductive structure to divide the first conductive structure into a first conductive wall and a second conductive wall separated from each other in the first direction,
wherein the first conductive wall is used for a local connection of the first circuit cell and the second conductive wall is used for a local connection of the second circuit cell.

2. The method of claim 1, wherein the formation of first conductive structure further comprises:
forming an opening between the first circuit cell and the second circuit cell in the first direction;
conformally forming a dielectric layer on sidewalls of the opening; and
forming a conductive material to fill the opening to form the first conductive structure.

3. The method of claim 2, wherein the opening has a rolling pin shape in a top view.

4. The method of claim 2, wherein a thickness of the dielectric layer in the first direction is in a range from about 7 nm to about 9 nm.

5. The method of claim 2, further comprising:
forming a dielectric structure between and in contact with the first conductive wall and the second conductive wall in the second direction, wherein the dielectric layer is in contact with the dielectric structure in the second direction.

6. The method of claim 5, wherein a thickness of the dielectric structure in the first direction is in a range from about 20 nm to about 24 nm.

7. The method of claim 1, wherein a thickness of the first conductive wall and the second conductive wall in the first direction is in a range from about 11 nm to about 13 nm.

8. The method of claim 1, further comprising:
forming a second conductive structure lengthwise overlapping a cell boundary of the first circuit cell, wherein the CFETs in the first circuit cell are between the first conductive structure and the second conductive structure in the first direction;
removing a portion of the second conductive structure to divide the second conductive structure into a third conductive wall and a fourth conductive wall separated from each other in the second direction,
wherein the third conductive wall and the fourth conductive wall are electrically connected to a voltage source to supply power for the first circuit cell.

9. The method of claim 8, wherein a width of the third conductive wall and the fourth conductive wall in the first direction is in a range from about 18 nm to about 22 nm.

10. The method of claim 1, further comprising:
forming a first source/drain contact over and electrically connected to the first conductive wall and a first source/drain feature of the second transistor of one of the CFETs in the first circuit cell; and
forming a second source/drain contact under and electrically connected to the first conductive wall and a second source/drain feature of the first transistors of the one of the CFETs in the first circuit cell.

11. A method for manufacturing a semiconductor structure, comprising:
forming a fin over a substrate, wherein the fin comprises first semiconductor layers and second semiconductor layers alternately stacked;
forming dummy gate structures over the fin;
forming p-type source/drain features on opposite sides of the dummy gate structures in a first direction;
forming n-type source/drain features over the p-type source/drain features;
replacing the dummy gate structures and the first semiconductor layers with gate structures wrapping around the second semiconductor layers;
forming a first conductive structure spaced apart from the gate structures in a second direction perpendicular to the first direction; and
removing a portion of the first conductive structure to divide the first conductive structure into a first conductive wall and a second conductive wall separated from each other in the second direction,
wherein the first conductive wall is electrically connected to one of the p-type source/drain features and one of the n-type source/drain features.

12. The method of claim 11, further comprising:
forming a first source/drain contact over and in contact with the first conductive wall and the one of the n-type source/drain features; and
forming a second source/drain contact under and in contact with the first conductive wall and the one of the p-type source/drain features.

13. The method of claim 12, wherein the one of the n-type source/drain features is in direct over the one of the p-type source/drain features.

14. The method of claim 12, wherein the one of the n-type source/drain features and the one of the p-type source/drain features are on opposite sides of one of the gate structures.

15. The method of claim 11, further comprising:
forming an opening adjacent to the gate structures in the second direction;
conformally forming a dielectric layer on sidewalls of the opening;
forming a conductive material to fill the opening to form a second conductive structure, wherein the gate structures are between the first conductive structure and the second conductive structure in the second direction;
removing a portion of the second conductive structure to divide the second conductive structure into a third conductive wall and a fourth conductive wall separated from each other in the first direction; and
forming a dielectric structure between and in contact with the third conductive wall and the fourth conductive wall in the first direction, wherein the dielectric layer is in contact with the dielectric structure in the second direction.

16. The method of claim 15, wherein a thickness of the dielectric layer in the second direction is in a range from about 7 nm to about 9 nm.

17. The method of claim 11, wherein a distance between the first conductive wall and the second conductive wall in the second direction is in a range from about 20 nm to about 24 nm.

18. The method of claim 11, wherein a distance between the first conductive wall and the gate structures in the second direction is in a range from about 7 nm to about 9 nm.

19. A semiconductor structure, comprising:
a first circuit cell comprising first complementary field-effect transistors (CFETs) arranged in a first direction;
a second circuit cell arranged with the first circuit cell in a second direction perpendicular to the first direction and comprising second CFETs arranged in the first direction;
a first conductive wall and a second conductive wall between the first CFETs and the second CFETs in the second direction;
a dielectric structure between and in contact with the first conductive wall and the second conductive wall in the second direction;
a dielectric layer wrapping around the first conductive wall, the second conductive wall, and the dielectric structure in a top view;
a first source/drain contact over and in contact with the first conductive wall and a first source/drain feature of the first CFETs; and
a second source/drain contact under and in contact with the first conductive wall and a second source/drain feature of the first CFETs, wherein the first source/drain feature is higher than the second source/drain feature.

20. The semiconductor structure of claim 19, further comprising:
a third conductive wall and a fourth conductive wall adjacent to the first CFETs and extending lengthwise in the first direction,
wherein the third conductive wall and the fourth conductive wall overlap a cell boundary of the first circuit cell in a top view,
wherein the third conductive wall and the fourth conductive wall are separated from each other in the first direction.
